(19) United States
(12) Patent Application Publication
(10) Pub. No.: US 2024/0412945 A1
(43) Pub. Date: Dec. 12, 2024

(54) ELECTRON BEAM WRITING METHOD, ELECTRON BEAM WRITING APPARATUS, AND NON-TRANSITORY MATERIAL COMPUTER-READABLE STORAGE MEDIUM WITH PROGRAMS STORED THEREIN

(71) Applicant: NuFlare Technology, Inc., Yokohama-shi (JP)

(72) Inventors: Haruyuki NOMURA, Yokohama-shi (JP); Noriaki NAKAYAMADA, Kamakura-shi (JP)

(73) Assignee: NuFlare Technology, Inc., Yokohama-shi (JP)

(21) Appl. No.: 18/732,049

(22) Filed: Jun. 3, 2024

(30) Foreign Application Priority Data
Jun. 12, 2023 (JP) 2023-096551

(51) Int. Cl. H01J 37/304; H01J 37/317

(52) U.S. Cl. CPC H01J 37/3045; H01J 37/3174; H01J 2237/30455

(57) ABSTRACT

An electron beam writing method includes calculating, in a case of writing a pattern with an electron beam on a target object which irreversibly deforms depending on a dose distribution of the electron beam, a first positional deviation amount of the pattern deviated from its design position because of an irreversible deformation of the target object after completion of writing processing, calculating, based on the first positional deviation amount, a correction amount for correcting a position of the pattern or an irradiation position of an electron beam in forming the pattern by irradiation of the electron beam on the target object, and performing, based on the correction amount, writing processing to write the pattern on the target object with an electron beam.

### CROSS-REFERENCE TO RELATED APPLICATION

This application is based upon and claims the benefit of priority from prior Japanese Patent Application No. 2023-096551 filed on Jun. 12, 2023 in Japan, the entire contents of which are incorporated herein by reference.

### BACKGROUND OF THE INVENTION

### Field of the Invention

Embodiments of the present invention relate to an electron beam writing method, an electron beam writing apparatus, and a program. For example, they relate to a method for writing while correcting a positional deviation with respect to a substrate which deforms irreversibly by irradiation with electron beams.

### Description of Related Art

The lithography technique which advances miniaturization of semiconductor devices is extremely important as a unique process whereby patterns are formed in semiconductor manufacturing. In recent years, with high integration of LSI, the line width (critical dimension) required for semiconductor device circuits is becoming increasingly finer year by year. The electron beam writing technique, which intrinsically has excellent resolution, is used for writing or “drawing” on a wafer and the like with electron beams.

For example, as a known example of employing the electron beam writing technique, there is a writing apparatus using multiple beams. Since it is possible for multiple beam writing to apply multiple beams at a time, the writing throughput can be greatly increased in comparison with single electron beam writing. For example, a writing apparatus employing the multiple beam system forms multiple beams by letting an electron beam emitted from an electron gun pass through a mask having a plurality of holes, performs blanking control for each beam, reduces each unblocked beam by an optical system, and deflects it by a deflector to irradiate a desired position on a target object or “sample”.

In associated with the prevalence of multiple patterning, PSM masks, or EUV masks, the accuracy requirement for the global pattern position in a mask is becoming more stringent year by year.

One of factors which degrade the accuracy of global pattern position is that, in a glass substrate serving as a target object, a reversible deformation occurs such as a thermal expansion caused by glass substrate heating due to electron beam irradiation and a subsequent contraction. The glass substrate deformation results in a problem that positional deviation occurs at a beam irradiation position or a pattern formation position. As a technique for solving this problem, there is disclosed that the pattern position is offset by performing calculation of a distortion caused by substrate deformation due to thermal expansion accompanied by bulk heating (e.g., refer to Japanese Patent Application Laid-open (JP-A) No. 2004-312030).

Meanwhile, as a technique for solving the above problem, a blanks maker manufacturing glass substrates developed a low-thermal expansion material (LTEM) substrate in which thermal expansion of the substrate itself is suppressed. In this LTEM substrate, since thermal expansion caused by temperature increase due to irradiation with electron beams is small, substrate deformation resulting from the thermal expansion can be suppressed, which has solved problems, such as positional deviation by reversible deformation accompanied by thermal expansion. However, it has turned out that an irreversible contraction phenomenon occurs in a glass substrate due to irradiation with electron beams. This has a background where the amount of beam irradiation has increased because the sensitivity of resist is lowered in order to improve the local dimensional accuracy, and where since the thermal expansion has become negligible because of prevalence of the LTEM substrate, relatively, the contraction phenomenon of a glass substrate has become revealed. Now, a problem arises because deformation due to an irreversible contraction phenomenon of the glass substrate degrades the global position accuracy of a beam irradiation position or a pattern formation position. This problem occurs both in multiple beam writing and in single beam writing.

### BRIEF SUMMARY OF THE INVENTION

According to one aspect of the present invention, an electron beam writing method includes
calculating, in a case of writing a pattern with an electron beam on a target object which irreversibly deforms depending on a dose distribution of the electron beam, a first positional deviation amount of the pattern deviated from its design position because of an irreversible deformation of the target object after completion of writing processing;
calculating, based on the first positional deviation amount, a correction amount for correcting one of a position of the pattern and an irradiation position of an electron beam in forming the pattern by irradiation of the electron beam on the target object; and
performing, based on the correction amount, writing processing to write the pattern on the target object with an electron beam.

According to another aspect of the present invention, an electron beam writing apparatus includes
a stage configured to mount thereon a target object which deforms irreversibly depending on a dose distribution of an electron beam;
a first positional deviation amount calculation circuit configured to calculate, in a case of writing a pattern with the electron beam on the target object, a first positional deviation amount of the pattern deviated from its design position because of an irreversible deformation of the target object after completion of the writing;
a correction amount calculation unit configured calculate, based on the first positional deviation amount, a correction amount for correcting one of a position of the pattern and an irradiation position of an electron beam in forming the pattern by irradiation of the electron beam on the target object; and
a writing mechanism configured to write the pattern on the target object with an electron beam, based on the correction amount.

According to yet another aspect of the present invention, a non-transitory computer-readable tangible storage medium storing a program for causing a computer to execute processing includes
calculating, in a case of writing a pattern with an electron beam on a target object which irreversibly deforms depending on a dose distribution of the electron beam, a first positional deviation amount of the pattern deviated from its design position because of an irreversible deformation of the target object after completion of writing processing;
storing the first positional deviation amount in a storage device; and
reading the first positional deviation amount from the storage device, calculating, based on the first positional deviation amount, a correction amount for correcting one of a position of the pattern and an irradiation position of an electron beam in forming the pattern by irradiation of the electron beam on the target object, and outputting the correction amount.

According to yet another aspect of the present invention, an electron beam writing method includes
calculating, in first writing processing for writing a first chip pattern with an electron beam on a target object which irreversibly depending on a dose distribution of the electron beam, a first positional deviation amount of the first chip pattern deviated from its design position because of an irreversible deformation of the target object generated by irradiation of an electron beam on the target object having been performed before irradiation of an electron beam currently performed in the first writing processing;
calculating, in second writing processing for writing a second chip pattern to be superimposed on the first chip pattern, a second positional deviation amount of the second chip pattern deviated from its design position because of an irreversible deformation of the target object generated by irradiation of an electron beam on the target object having been performed before irradiation of an electron beam currently performed in the second writing processing;
calculating, based on a difference between the second positional deviation amount and the first positional deviation amount, a correction amount for correcting one of a position of the pattern and an irradiation position of the electron beam in a case of forming the pattern on the target object by applying the electron beam to the target object in the second writing processing; and
performing the first writing processing of writing the first chip pattern on the target object with an electron beam, and the second writing processing of writing the second chip pattern on the target object with an electron beam, based on the correction amount.

According to yet another aspect of the present invention, an electron beam writing apparatus includes a stage configured to mount thereon a target object which deforms irreversibly depending on a dose distribution of an electron beam;
a positional deviation amount calculation circuit configured to calculate, in first writing processing for writing a first chip pattern with the electron beam on the target object, a first positional deviation amount of the first chip pattern deviated from its design position because of an irreversible deformation of the target object generated by irradiation of an electron beam on the target object having been performed before irradiation of an electron beam currently performed in the first writing processing, and to calculate, in second writing processing for writing a second chip pattern to be superimposed on the first chip pattern, a second positional deviation amount of the second chip pattern deviated from its design position because of an irreversible deformation of the target object generated by irradiation of an electron beam on the target object having been performed before irradiation of an electron beam currently performed in the second writing processing;
a correction amount calculation circuit configured to calculate, based on a difference between the second positional deviation amount and the first positional deviation amount, a correction amount for correcting one of a position of the pattern and an irradiation position of an electron beam in a case of forming the pattern on the target object by applying the electron beam to the target object in the second writing processing; and
a writing mechanism configured to perform the first writing processing of writing the first chip pattern on the target object with an electron beam, and the second writing processing of writing the second chip pattern on the target object with an electron beam, based on the correction amount.

According to yet another aspect of the present invention, a non-transitory computer-readable tangible storage medium storing a program for causing a computer to execute processing includes
calculating, in first writing processing for writing a first chip pattern with an electron beam on a target object which deforms irreversibly depending on a dose distribution of the electron beam, a first positional deviation amount of the first chip pattern deviated from its design position because of an irreversible deformation of the target object generated by irradiation of an electron beam on the target object having been performed before irradiation of an electron beam currently performed in the first writing processing;
calculating, in second writing processing for writing a second chip pattern to be superimposed on the first chip pattern, a second positional deviation amount of the second chip pattern deviated from its design position because of an irreversible deformation of the target object generated by irradiation of an electron beam on the target object having been performed before irradiation of an electron beam currently performed in the second writing processing;
storing the first positional deviation amount and the second positional deviation amount in a storage device; and
reading the first positional deviation amount and the second positional deviation amount from the storage device, calculating, based on a difference between the second positional deviation amount and the first positional deviation amount, a correction amount for correcting one of a position of the pattern and an irradiation position of an electron beam in a case of forming the pattern on the target object by applying the electron beam to the target object in the second writing processing, and outputting the correction amount.

### BRIEF DESCRIPTION OF THE DRAWINGS

FIG. 1 is a schematic diagram showing a configuration of a writing apparatus according to a first embodiment;

FIG. 2 is a conceptual diagram showing a configuration of a shaping aperture array substrate according to the first embodiment;

FIG. 3 is a sectional view showing a configuration of a blanking aperture array mechanism according to the first embodiment;

FIG. 4 is an illustration showing an example of an evaluation substrate according to the first embodiment;

FIG. 5 is an illustration showing an example of a positional deviation amount of an evaluation substrate, and an example of deformation of a substrate according to the first embodiment;

FIG. 6 is an illustration showing an example of a state at the time of beam irradiation to an evaluation substrate according to the first embodiment;

FIG. 7 is an illustration showing an example of a stress state resulting from beam irradiation to an evaluation substrate according to the first embodiment;

FIG. 8 is an illustration showing an example of a positional deviation state of a substrate surface according to a comparative example 1 of the first embodiment;

FIG. 9 is an illustration showing an example of a deformation of a substrate surface according to the comparative example 1 of the first embodiment;

FIG. 10 is an illustration showing an example of a positional deviation state of a substrate surface according to the first embodiment;

FIG. 11 is a flowchart showing an example of main steps of a writing method according to the first embodiment;

FIG. 12 is a flowchart showing another example of main steps of a writing method according to the first embodiment;

FIG. 13 is a graph showing an example of a relationship between a substrate contraction ratio and a dose according to the first embodiment;

FIG. 14 is an illustration showing an example of a model by a finite element method according to the first embodiment;

FIG. 15 is a conceptual diagram showing an example of a writing operation according to the first embodiment;

FIG. 16 is an illustration showing an example of an irradiation region of multiple beams and a writing target pixel according to the first embodiment;

FIG. 17 is an illustration explaining an example of a multi-beam writing operation according to the first embodiment;

FIG. 18 is a conceptual diagram showing a configuration of a writing apparatus according to a second embodiment;

FIG. 19 is an illustration explaining a method of two-stroke writing according to the second embodiment;

FIG. 20 is an illustration showing an example of a positional deviation state of a substrate surface according to a comparative example of the second embodiment;

FIG. 21 is an illustration showing an example of a positional deviation state of a substrate surface according to the second embodiment;

FIG. 22 is a flowchart showing an example of main steps of a writing method according to the second embodiment;

FIG. 23 is an illustration showing an example of a positional deviation state of a substrate surface according to a third embodiment;

FIG. 24 is a conceptual diagram showing a configuration of a writing apparatus according to a fourth embodiment;

FIG. 25 is an illustration showing an example of a positional deviation state of a substrate surface according to a comparative example of the fourth embodiment;

FIG. 26 is an illustration showing an example of a positional deviation state of a substrate surface according to the fourth embodiment;

FIG. 27 is a flowchart showing some portions of an example of main steps of a writing method according to the fourth embodiment;

FIG. 28 is a flowchart showing other portions of the example of the main steps of the writing method according to the fourth embodiment;

FIG. 29 is an illustration showing an example of a target object surface on which an alignment mark is formed according to the fourth embodiment;

FIG. 30 is an illustration showing an example of a mark position after the first writing processing according to the fourth embodiment;

FIG. 31 is an illustration showing an example of a mark position after the second writing processing according to the fourth embodiment; and

FIG. 32 is an illustration showing an example of a positional deviation state of a substrate surface according to a fifth embodiment.

### DETAILED DESCRIPTION OF THE INVENTION

Embodiments below provide a method and apparatus which can correct positional deviation of a beam irradiation position or a pattern formation position caused by irreversible deformation of a target object due to irradiation with electron beams.

Embodiments below describe a configuration in which an electron beam is used as an example of a charged particle beam. The charged particle beam is not limited to the electron beam, and other charged particle beam such as an ion beam may also be used. Further, Embodiments below describe the case of using multiple electron beams. However, the correction method below is not limited to the case of multiple beams, and a single beam case is also applicable.

### First Embodiment

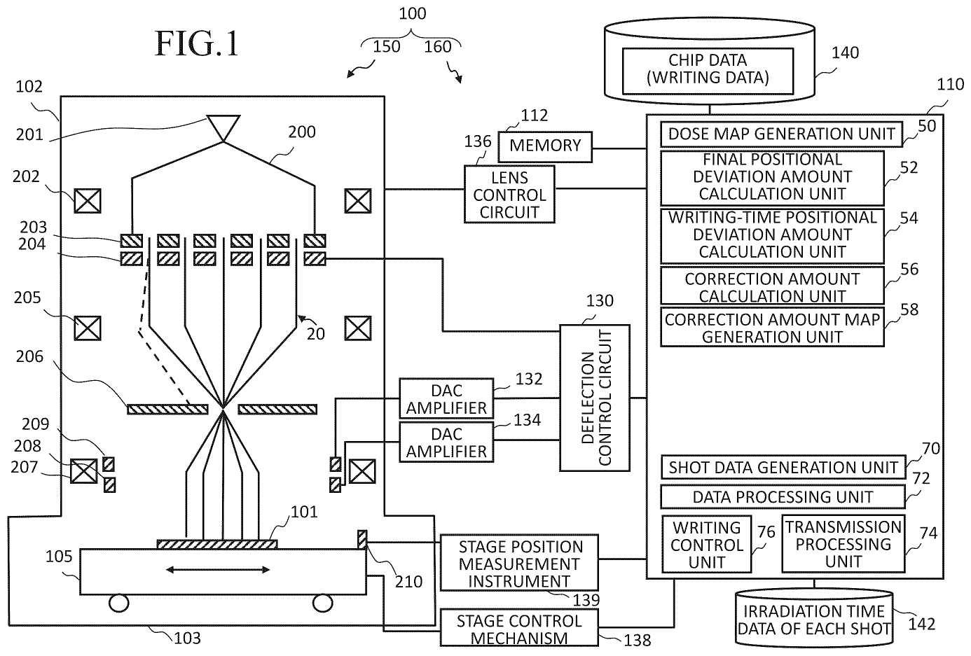

FIG. 1 is a schematic diagram showing a configuration of a writing or “drawing” apparatus according to a first embodiment. As shown in FIG. 1, a writing apparatus 100 includes a writing mechanism 150 and a control system circuit 160. The writing apparatus 100 is an example of a multiple charged particle beam writing apparatus and a multiple charged particle beam exposure apparatus. The writing mechanism 150 includes an electron optical column 102 (electron beam column) and a writing chamber 103. In the electron optical column 102, there are disposed an electron gun 201, an illumination lens 202, a shaping aperture array substrate 203, a blanking aperture array mechanism 204, a reducing lens 205, a limiting aperture substrate 206, an objective lens 207, a deflector 208, and a deflector 209.

In the writing chamber 103, an XY stage 105 is disposed. On the XY stage 105, there is placed a target object or “sample” 101 such as a mask serving as a writing target substrate when writing (exposure) is performed. The target object 101 is, for example, an exposure mask used when fabricating semiconductor devices, or a semiconductor substrate (silicon wafer) for fabricating semiconductor devices. The target object 101 may be, for example, a mask blank on which resist has been applied and nothing has yet been written. A low-thermal expansion material (LTEM) substrate is used as a glass substrate of the target object 101.

On the XY stage 105, a mirror 210 for measuring the position of the XY stage 105 is placed.

The control system circuit 160 includes a control computer 110, a memory 112, a deflection control circuit 130, digital-analog converter (DAC) amplifier units 132 and 134, a lens control circuit 136, a stage control mechanism 138, a stage position measurement instrument 139, and storage devices 140 and 142 such as magnetic disk drives. The control computer 110, the memory 112, the deflection control circuit 130, the lens control circuit 136, the stage control mechanism 138, the stage position measurement instrument 139, and the storage devices 140 and 142 are connected to each other through a bus (not shown). The DAC amplifier units 132 and 134 and the blanking aperture array mechanism 204 are connected to the deflection control circuit 130. The deflector 209 is composed of at least four electrodes (or “four poles”), and controlled by the deflection control circuit 130 through the DAC amplifier unit 132 disposed for each electrode. The deflector 208 is composed of at least four electrodes (or “four poles”), and controlled by the deflection control circuit 130 through the DAC amplifier unit 134 disposed for each electrode. Electromagnetic lenses such as the illumination lens 202, the reducing lens 205, and the objective lens 207 are controlled by the lens control circuit 136.

The position of the XY stage 105 is controlled by the drive of each axis motor (not shown) which is controlled by the stage control mechanism 138. Based on the principle of laser interferometry, the stage position measurement instrument 139 measures the position of the XY stage 105 by receiving a reflected light from the mirror 210.

In the control computer 110, there are arranged a dose map generation unit 50, a final positional deviation amount calculation unit 52, a writing-time positional deviation amount calculation unit 54, a correction amount calculation unit 56, a correction amount map generation unit 58, a shot data generation unit 70, a data processing unit 72, a transmission processing unit 74, and a writing control unit 76. Each of the “ . . . units” such as the dose map generation unit 50, the final positional deviation amount calculation unit 52, the writing-time positional deviation amount calculation unit 54, the correction amount calculation unit 56, the correction amount map generation unit 58, the shot data generation unit 70, the data processing unit 72, the transmission processing unit 74, and the writing control unit 76 includes processing circuitry. The processing circuitry includes, for example, an electric circuit, a computer, a processor, a circuit board, a quantum circuit, a semiconductor device, or the like. Each “ . . . unit” may use common processing circuitry (the same processing circuitry), or different processing circuitry (separate processing circuitry). Information input/output to/from the dose map generation unit 50, the final positional deviation amount calculation unit 52, the writing-time positional deviation amount calculation unit 54, the correction amount calculation unit 56, the correction amount map generation unit 58, the shot data generation unit 70, the data processing unit 72, the transmission processing unit 74, and the writing control unit 76, and information being operated are stored in the memory 112 each time.

Writing operations of the writing apparatus 100 are controlled by the writing control unit 76. Processing of transmitting irradiation time data of each shot to the deflection control circuit 130 is controlled by the transmission control unit 74.

Writing data (chip data) is input from the outside of the writing apparatus 100, and stored in the storage device 140. Chip data defines information on a plurality of figure patterns configuring a chip pattern. Specifically, for example, coordinates of each vertex are defined for each figure pattern. Further, a figure code, a size, and the like may also be preferably defined.

FIG. 1 shows a configuration necessary for describing the first embodiment. Other configuration elements generally necessary for the writing apparatus 100 may also be included therein.

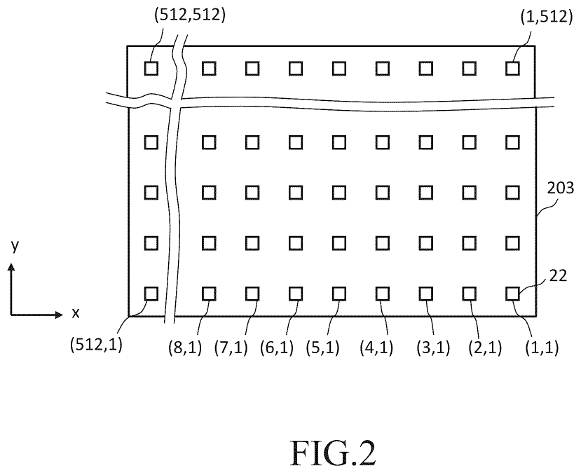

FIG. 2 is a conceptual diagram showing a configuration of a shaping aperture array substrate according to the first embodiment. As shown in FIG. 2, holes (openings) 22 of p rows long (length in the y direction) and q columns wide (width in the x direction) (p≥2, q≥2) are formed, like a matrix, at a predetermined arrangement pitch in the shaping aperture array substrate 203. In the case of FIG. 2, for example, holes (openings) 22 of 512×512, that is 512 holes in the y direction and 512 holes in the x direction, are formed. The number of holes 22 is not limited thereto. For example, it is also preferable to form the holes 22 of 32×32. Each of the holes 22 is a rectangle (including square) having the same dimension and shape as each other. Alternatively, each of the holes 22 may be a circle with the same diameter as each other. The multiple beams 20 are formed by letting portions of an electron beam 200 individually pass through a corresponding one of a plurality of holes 22. In other words, the shaping aperture array substrate 203 forms and emits the multiple beams 20. The shaping aperture array substrate 203 is an example of an emission source of the multiple beams 20.

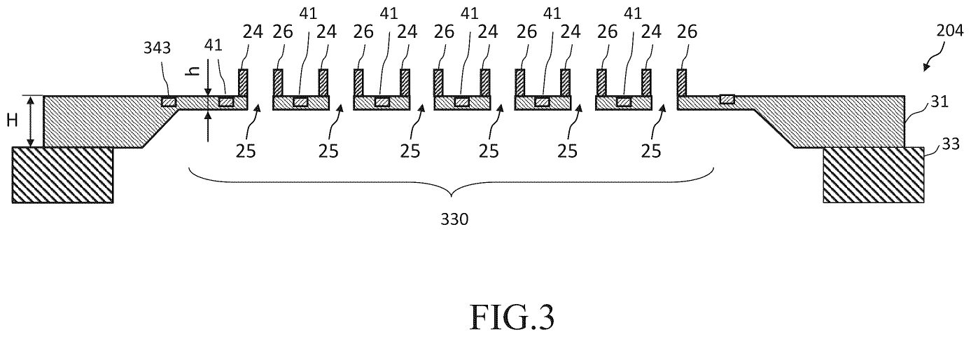

FIG. 3 is a sectional view showing a configuration of a blanking aperture array mechanism according to the first embodiment. In the blanking aperture array mechanism 204, as shown in FIG. 3, a blanking aperture array substrate 31 being a semiconductor substrate made of silicon, etc. is disposed on a support substrate 33. In a membrane region 330 at the center of the blanking aperture array substrate 31, a plurality of passage holes 25 (openings), through each of which a corresponding one of the multiple beams 20 passes, are formed at positions each corresponding to each hole 22 in the shaping aperture array substrate 203 shown in FIG. 2. A pair of a control electrode 24 and a counter electrode 26, (blanker: blanking deflector), is arranged in a manner such that the electrodes 24 and 26 are opposite to each other across a corresponding one of the plurality of the passage holes 25. A control circuit 41 (logic circuit) which applies a deflection voltage to the control electrode 24 for the passage hole 25 concerned is disposed inside the blanking aperture array substrate 31 and close to each corresponding passage hole 25. The counter electrode 26 for each beam is grounded.

In the control circuit 41, an amplifier (not shown) (an example of a switching circuit) is arranged. As an example of the amplifier, a CMOS (Complementary MOS) inverter circuit serving as a switching circuit is disposed. In regard to inputs (IN) to the CMOS inverter circuit, either an L (low) potential (e.g., ground potential) lower than a threshold voltage, or an H (high) potential (e.g., 1.5 V) higher than or equal to the threshold voltage is applied as a control signal. According to the first embodiment, in a state where an L potential is applied to the input (IN) of the CMOS inverter circuit, the output (OUT) of the CMOS inverter circuit, which is to be applied to the control circuit 41, becomes a positive potential (Vdd), and then, a corresponding beam is deflected by an electric field due to a potential difference from the ground potential of the counter electrode 26, and is controlled to be in a beam OFF condition by being blocked by the limiting aperture substrate 206. In contrast, in a state (active state) where an H potential is applied to the input (IN) of the CMOS inverter circuit, the output (OUT) of the CMOS inverter circuit becomes a ground potential, and therefore, since there is no potential difference from the ground potential of the counter electrode 26, a corresponding beam is not deflected, and is controlled to be in a beam ON condition by passing through the limiting aperture substrate 206. Blanking control is provided by such deflection.

Next, operations of the writing mechanism 150 will be described. The electron beam 200 emitted from the electron gun 201 (emission source) almost perpendicularly (e.g., vertically) illuminates the whole of the shaping aperture array substrate 203 by the illumination lens 202. A plurality of rectangular holes 22 (openings) are formed in the shaping aperture array substrate 203. The region including all of the plurality of holes 22 is irradiated with the electron beam 200. For example, rectangular multiple beams (a plurality of electron beams) 20 are formed by letting portions of the electron beam 200 applied to the positions of the plurality of holes 22 individually pass through a corresponding one of the plurality of holes 22 in the shaping aperture array substrate 203. The multiple beams 20 individually pass through corresponding blankers of the blanking aperture array mechanism 204. The blanker provides blanking control such that a corresponding beam individually passing becomes in an ON condition during a set writing time (irradiation time).

The multiple beams 20 having passed through the blanking aperture array mechanism 204 are reduced by the reducing lens 205, and travel toward the hole in the center of the limiting aperture substrate 206. Then, the electron beam which was deflected by the blanker of the blanking aperture array mechanism 204 deviates (shifts) from the hole in the center of the limiting aperture substrate 206 and is blocked by the limiting aperture substrate 206. In contrast, the electron beam which was not deflected by the blanker of the blanking aperture array mechanism 204 passes through the hole in the center of the limiting aperture substrate 206 as shown in FIG. 1. Thus, the limiting aperture substrate 206 blocks each beam which was deflected to be in the OFF state by the blanker of the blanking aperture array mechanism 204. Then, one shot of each beam is formed by a beam which has been made during a period from becoming beam ON to becoming beam OFF and has passed through the limiting aperture substrate 206. The multiple beams 20 having passed through the limiting aperture substrate 206 are focused by the objective lens 207 so as to be a pattern image of a desired reduction ratio. Then, all of the multiple beams 20 having passed through the limiting aperture substrate 206 are collectively deflected in the same direction by the deflectors 208 and 209 in order to irradiate respective beam irradiation positions on the target object 101. When, for example, the XY stage 105 is continuously moving, tracking control is performed by the deflector 208 so that the beam irradiation position may follow the movement of the XY stage 105. Ideally, the multiple beams 20 irradiating at a time are aligned at the pitch obtained by multiplying the arrangement pitch of a plurality of holes 22 in the shaping aperture array substrate 203 by the desired reduction ratio described above.

By using an LTEM substrate as a writing target object, the thermal expansion due to irradiation with electron beams such as a single beam or multiple beams may hardly occur. Therefore, the problem of positional deviation of the writing position because of thermal expansion has been improved greatly to be a negligible extent. However, it has turned out that an irreversible contraction phenomenon arises in the glass substrate used as the target object 101 because dose amounts are accumulated through a plurality of times of irradiation with electron beams.

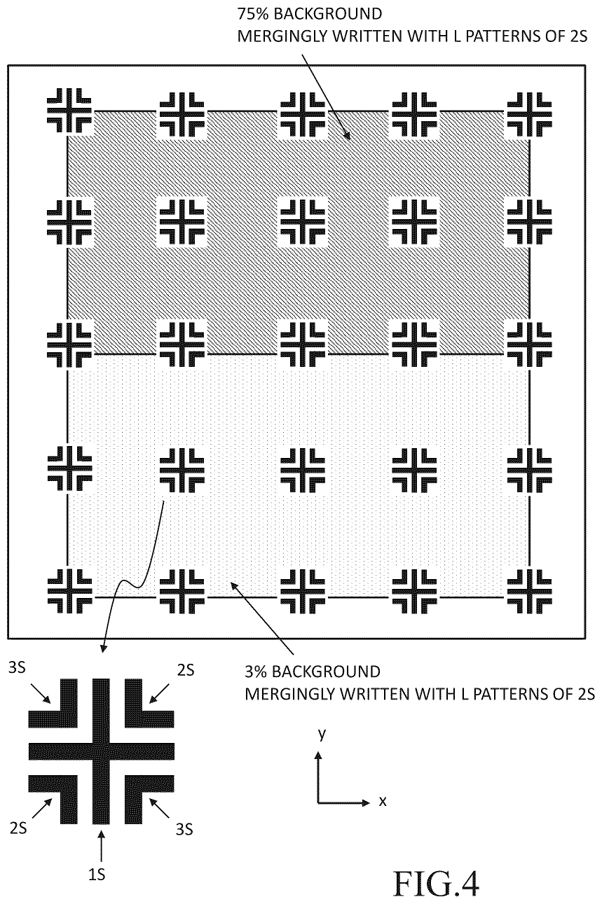

FIG. 4 is an illustration showing an example of an evaluation substrate according to the first embodiment. An LTEM substrate is used as an evaluation substrate. Specifically, a mask blank is used, in which a chromium (Cr) film, for example, is formed on the LTEM substrate and a resist film is formed on the Cr film. FIG. 4 shows an example of a pattern in the state where a writing process has been performed three times. Each writing process is performed in the y direction from the lower side to the upper side of the evaluation substrate. In the first writing process (1S), a plurality of cross patterns are written in a grid form on the whole evaluation substrate. In the second writing process (2S), L patterns are written close to each cross pattern, for example, at the upper right and the lower left of each cross pattern, and rectangular patterns whose pattern densities are different from each other at the lower half and the upper half of the evaluation substrate are written as a background of a plurality of cross patterns. For example, the pattern density of the background at the lower half part which is written in the first half is set to 3%. The pattern density of the background at the upper half part which is written in the latter half is set to 75%. In the third writing process (3S), L patterns are written close to each cross pattern, for example, at the upper left and the lower right of each cross pattern. After each writing process, the position of each written pattern is measured by a position measurement instrument (not shown).

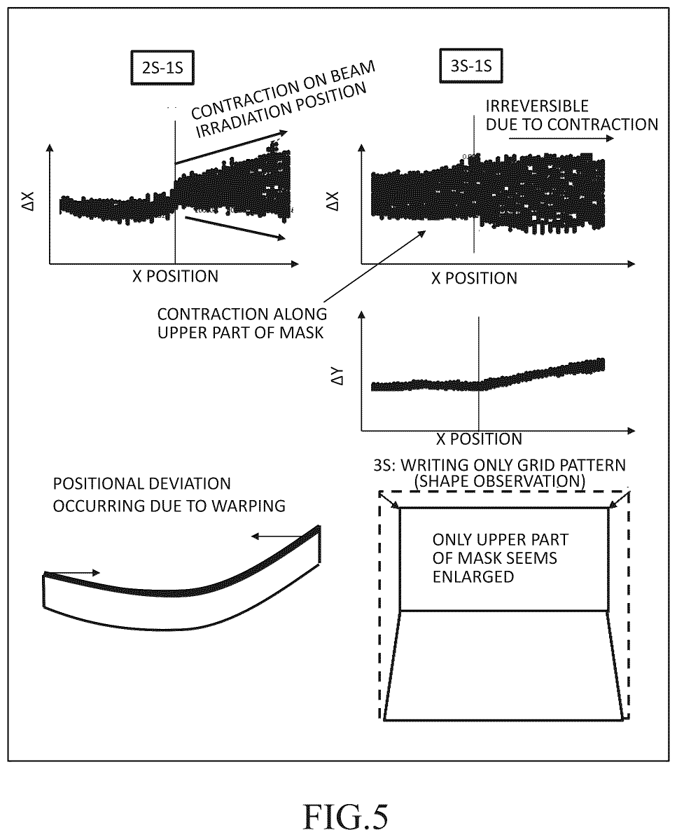

FIG. 5 is an illustration showing an example of a positional deviation amount of an evaluation substrate, and an example of deformation of a substrate according to the first embodiment. The upper left graph (2S−1S) of FIG. 5 shows an example of an x-direction positional deviation amount Δx in the state, (2S−1S), where the position of each pattern after the writing process 1S is subtracted from the position of each pattern after the writing process 2S. As shown in the graph of (2S−1S), it turns out that the positional deviation amount Δx is small in the pattern whose background has a pattern density of 3%, whereas, in the pattern whose background has a pattern density of 75%, the positional deviation amount Δx increases in associated with an increase of the region where the writing process has been performed. This means that deformation by contraction of the glass substrate increases depending on the dose amount. Further, the upper right graphs (3S−1S) of FIG. 5 show an example of an x-direction positional deviation amount Δx and a y-directional positional deviation amount Δy in the state, (3S−1S), where the position of each pattern after the writing process 1S is subtracted from the position of each pattern after the writing process 3S. As shown in the graph of (3S−1S), the positional deviation amount Δx of 2S still remains after 3S. It turns out that the lower half of the substrate also deforms corresponding to the contraction of the upper half of the substrate, and since deviation occurs in the position of the substrate at 3S, the positional deviation amount Δx increases. Further, it turns out that, with respect also to the y direction in the upper half of the substrate, the positional deviation amount ΔY increases gradually. This is because that, as shown in the lower right side of FIG. 5, the upper half of the substrate is irradiated with a comparative large amount of beam, and therefore, deformation occurs because of a large contraction in the upper half. As shown in the figure, by 2S, deformation because of a large contraction occurs in the upper half of the substrate.

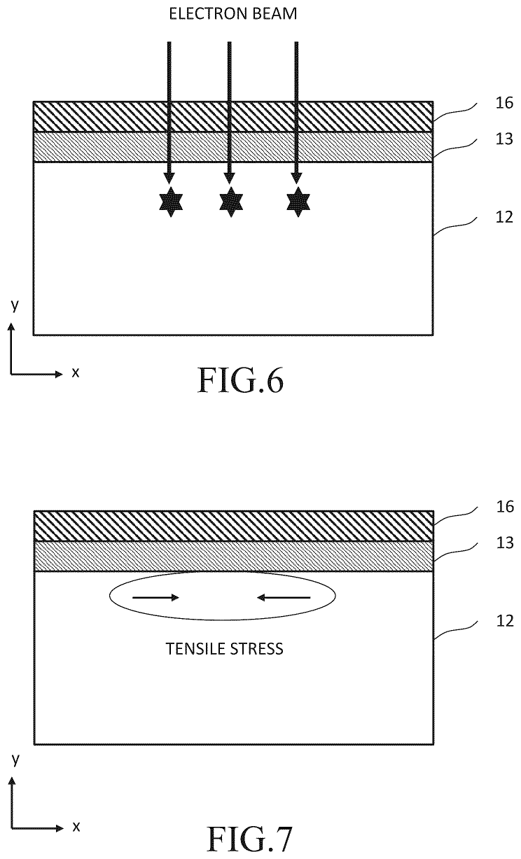

FIG. 6 is an illustration showing an example of a state at the time of beam irradiation to an evaluation substrate according to the first embodiment.

FIG. 7 is an illustration showing an example of a stress state resulting from beam irradiation to an evaluation substrate according to the first embodiment.

As described above, as the evaluation substrate of FIG. 6, a mask blank is used, in which, for example, a chromium (Cr) film 13 is formed on an LTEM substrate 12 and a resist film 16 is formed on the Cr film 13. When the evaluation substrate is irradiated with an electron beam, the electron beam reaches the LTEM substrate 12 and penetrates it up to a depth of about several tens of μm from the surface of the LTEM substrate 12. By this, an irreversible local contraction occurs on the irradiation position of the LTEM substrate 12. If a plurality of portions are irradiated with beams, a tensile stress occurs in the vicinity of the substrate surface due to a local contraction, in the whole region having been irradiated with beams. By this, in the vicinity of the surface of the LTEM substrate 12, an irreversible deformation occurs due to a contraction phenomenon. Since a deformation having a depth of, for example, 20 μm is small volume-wise compared to the width dimension (e.g., 6.35 mm) of the LTEM substrate 12, the thermal deformation property of the whole substrate does not change. Therefore, a reversible deformation resulting from a thermal expansion can be negligible.

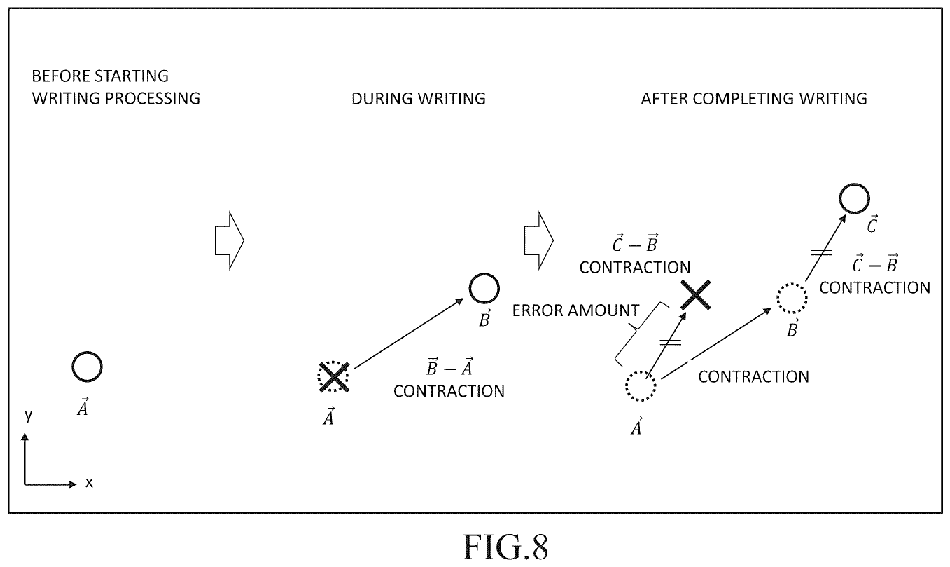

FIG. 8 is an illustration showing an example of a positional deviation state of a substrate surface according to a comparative example 1 of the first embodiment.

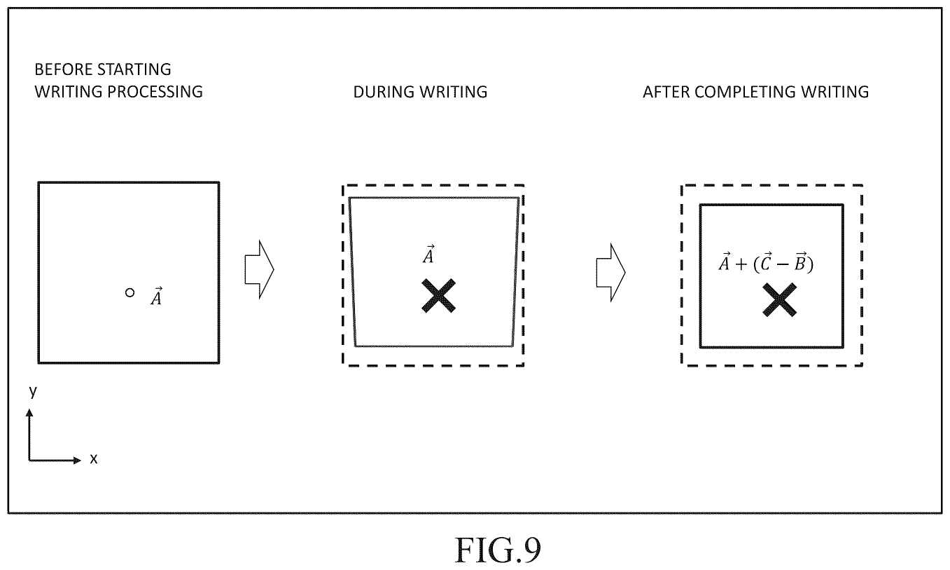

FIG. 9 is an illustration showing an example of a deformation of a substrate surface according to the comparative example 1 of the first embodiment.

FIGS. 8 and 9 show a state before starting writing processing, a state during writing at a desired position, and a state after completing writing processing.

In FIG. 8, the vector A indicates a design beam irradiation position. While the writing processing proceeds for the target LTEM substrate, at the time of writing the position of the vector A, the position of the vector A before starting writing processing has physically moved to the position of the vector B because a deformation due to contraction of the substrate occurred as shown in FIG. 9. Along with the writing processing proceeds, at the time of completion of the writing processing for the whole substrate, the position of the vector A before starting writing processing has physically moved to the position of the vector C because of a further deformation as shown in FIG. 9. Therefore, if the position of the vector A before starting writing processing is written as it is, at the time of completion of the writing processing of the whole substrate, the written beam irradiation position has deviated, by a vector of (vector C−vector B), from the position of the vector A before starting writing processing to the moved position (vector A+(vector C−vector B)). Then, according to the first embodiment, the writing-time irradiation position (pattern formation position) is corrected in order to let the beam irradiation position after completion of the writing processing be the position of the vector A before starting writing processing, even in the case of an irreversible deformation occurring in the substrate.

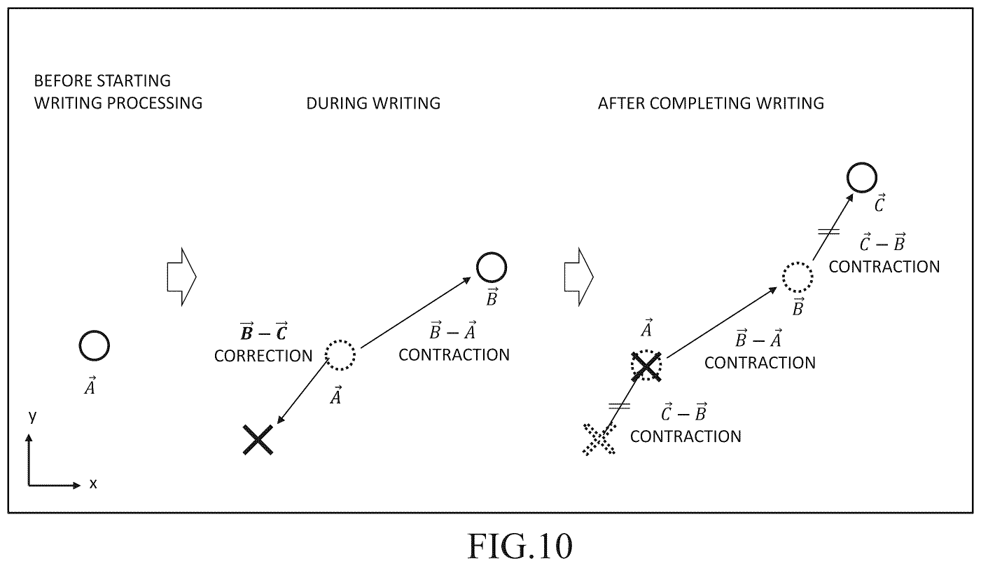

FIG. 10 is an illustration showing an example of a positional deviation state of a substrate surface according to the first embodiment. The example of deformation of a substrate surface according to the first embodiment is the same as that of FIG. 9. In FIG. 10, the vector A indicates a design beam irradiation position. While the writing process proceeds for the target LTEM substrate, the position of the vector A before starting writing processing has physically moved to the position of the vector B at the time of writing the position of the vector A because a deformation due to contraction of the substrate occurred as shown in FIG. 9. Along with the writing process proceeds, the position of the vector A before starting writing processing has physically moved to the position of the vector C at the time of completion of the writing process of the whole substrate because of a further deformation as shown in FIG. 9. Therefore, at the time of writing, the position corrected, by a vector of (vector B−vector C), from the position of the vector A before starting writing processing to a corrected position (vector A+(vector B−vector C)) is written as a beam irradiation position (or a pattern formation position). Thereby, at the time of completion of the writing processing for the whole substrate, the written beam irradiation position (or pattern formation position) can be the position of the vector A being the position moved from the position (vector A+(vector B−vector C)) by a vector of (vector C−vector B).

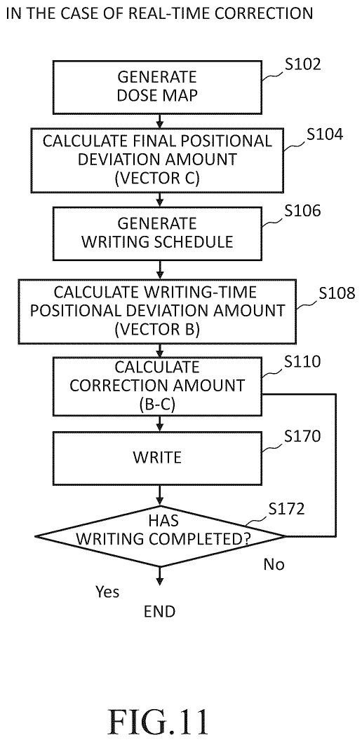

FIG. 11 is a flowchart showing an example of main steps of a writing method according to the first embodiment. FIG. 11 shows a flowchart in the case where writing processing is performed in a real-time mode of executing a calculation process for correcting a beam irradiation position (or pattern formation position) in the next region while performing a writing operation. In FIG. 11, the writing method according to the first embodiment executes a series of steps: a dose map generation step (S102), a final positional deviation amount (vector C) calculation step (S104), a writing schedule generation step (S106), a writing-time positional deviation amount (vector B) calculation step (S108), a correction amount calculation step (S110), a writing step (S170), and a determination step (S172).

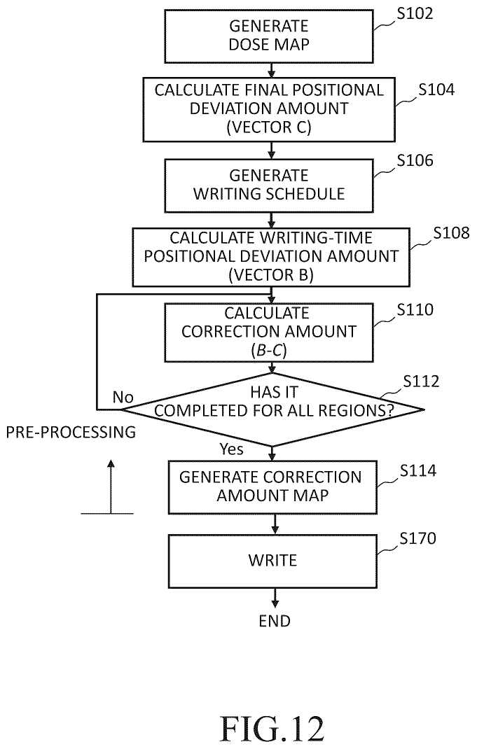

FIG. 12 is a flowchart showing another example of main steps of a writing method according to the first embodiment. FIG. 12 shows a flowchart in the case where writing processing is performed in a pre-processing mode of starting a writing operation after performing a calculation process, as a pre-process, for correcting beam irradiation positions (or pattern formation positions) in all the regions. In FIG. 12, the writing method according to the first embodiment executes a series of steps: the dose map generation step (S102), the final positional deviation amount (vector C) calculation step (S104), the writing schedule generation step (S106), the writing-time positional deviation amount (vector B) calculation step (S108), the correction amount calculation step (S110), a determination step (S112), a correction amount map generation step (114), and the writing step (S170).

Writing processing proceeds for each stripe region, to be described later, obtained by dividing in the y direction the writing region of the target object 101. In a real-time mode, the writing operation for the k-th stripe region and the correction calculation processing for the (k+m)th stripe region are carried out at the same period. In the preprocessing mode, the writing operation is started after completing the correction calculation processing of all the stripe regions.

In the dose map generation step (S102), the dose map generation unit 50 generates a dose map in which a dose is defined for each pixel to be described later. Specifically, it operates as follows: The dose map generation unit 50, first, virtually divides the writing region (for example, stripe region) into a plurality of proximity mesh regions (mesh regions for proximity effect correction calculation) by a predetermined size. The size of the proximity mesh region is preferably about 1/10 of the influence range of the proximity effect, such as about 1 μm. The dose map generation unit 50 reads writing data from the storage device 140, and calculates, for each proximity mesh region, a pattern area density ρ″ of a pattern arranged in the proximity mesh region concerned.

Next, the dose map generation unit 50 calculates, for each proximity mesh region, a proximity effect correction irradiation coefficient Dp(x) for correcting a proximity effect. An unknown proximity effect correction irradiation coefficient Dp(x) can be defined by a threshold value model for proximity effect correction, which is the same as the one used in a conventional method, where a backscatter coefficient η, a dose threshold value Dth of a threshold value model, a pattern area density ρ″, and a distribution function g(x) are used.

Next, the dose map generation unit 50 calculates, for each pixel, an incident dose D(x) (amount of dose) with which the pixel concerned is irradiated. The incident dose D(x) can be calculated, for example, by multiplying a base dose D_{base} by a proximity effect correction irradiation coefficient Dp and a pattern area density ρ′. The base dose D_{base} can be defined by Dth/(½+η), for example. Thereby, it is possible to obtain an incident dose D(x) for each pixel, for which a proximity effect has been corrected, based on layout of a plurality of figure patterns defined by the writing data. Alternatively, the dose map generation unit 50 calculates, for each pixel, an irradiation coefficient for irradiation to the pixel concerned. The irradiation coefficient d(x) can be obtained by multiplying a proximity effect correction irradiation coefficient Dp by a pattern area density ρ′, for example. In other words, the irradiation coefficient d(x) can be calculated as a modulation rate of the base dose D_{base}. Thereby, a dose (irradiation coefficient) d(x) can be obtained not as an absolute value of a dose but as a relative value standardized by defining the base dose D_{base} to be 1.

Next, the dose map generation unit 50 generates a dose map whose element is a dose of each pixel. In other words, each pixel (position) (x, y) and its dose D (or d) are relatedly defined. The generated dose map is stored in the storage device 142. The dose map generation unit 50 generates a dose map with respect to the whole of writing processing performed in accordance with the writing data (chip data).

In the final positional deviation amount (vector C) calculation step (S104), in the case of writing a pattern with electron beams on the target object 101 which irreversibly deforms depending on an electron beam dose distribution, the final positional deviation amount calculation unit 52 calculates a final positional deviation amount (the first positional deviation amount) deviated from a design pattern position because of an irreversible deformation of the target object 101 after completion of the writing processing. In other words, the final positional deviation amount calculation unit 52 calculates, in the case of writing a pattern with electron beams on the target object 101 which irreversibly deforms by electron beam irradiation, a final positional deviation amount (the first positional deviation amount) of a pattern formation position or a beam irradiation position, from a design position, deviated because of an irreversible deformation of the target object 101 after completion of the writing processing. Specifically, the final positional deviation amount calculation unit 52 calculates a positional deviation amount (vector C) of each position after completion of the writing processing for the target object 101.

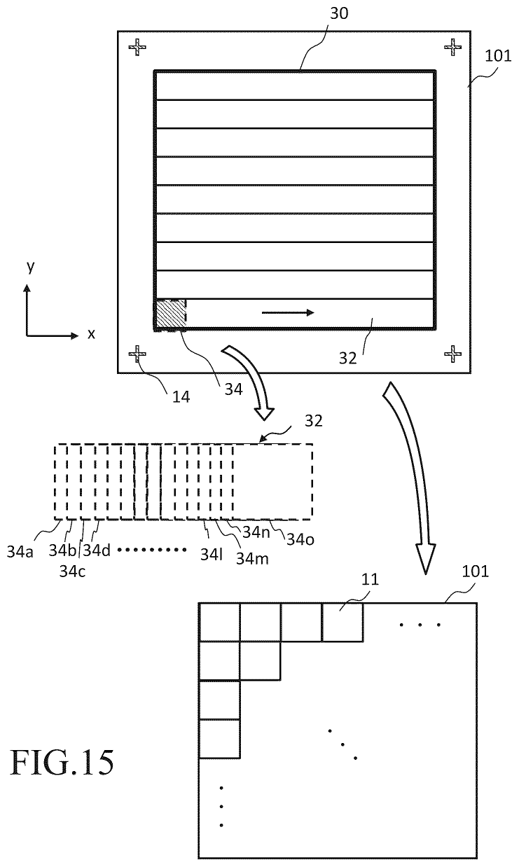

The influence range of the global positional deviation amount is from about several hundreds of μm to about several mm. Therefore, the influence range of the global positional deviation amount is larger than the beam array size (x direction and y direction), such as several tens of μm, of the multiple beams 20. Then, first, the final positional deviation amount calculation unit 52 virtually divides the region of the target object 101 surface into a plurality of global mesh regions 11 by a predetermined size as shown in FIG. 15. The size of the global mesh region 11 is preferably about 1/10 of the influence range of the global positional deviation amount, such as from about several tens of μm to about several hundreds of μm. For example, when the beam array size is about 80 μm, the size of the global mesh region 11 is preferably set to be about its half, namely, about 40 μm. However, the size of the global mesh region 11 is not limited to be smaller than the beam array size, and may be equal to or larger than the beam array size.

The final positional deviation amount calculation unit 52 calculates the vector C at a representative point (e.g., center position) in each global mesh region 11 (position). Each vector C is calculated as a final positional deviation amount (dxfinal-i, dyfinal-i). i indicates the index of each global mesh region 11. The final positional deviation amount of the global mesh region 11 where a pattern formation position or a beam irradiation position is included corresponds to the final positional deviation amount of the formation position of the pattern concerned or the beam irradiation position. The final positional deviation amount (dxfinal-i, dyfinal-i) of each global mesh region 11 is depending on a dose (irradiation coefficient) defined in the dose map, and can be calculated using a finite element method, for example.

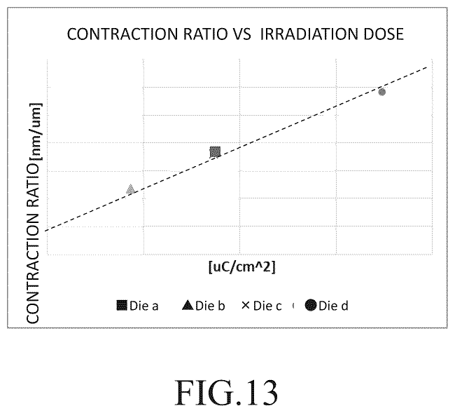

FIG. 13 is a graph showing an example of a relationship between a substrate contraction ratio and a dose according to the first embodiment. In FIG. 13, the ordinate axis represents a contraction ratio, and the abscissa axis represents a dose. In the example of FIG. 13, die a to die d are written at variable pattern area densities p and irradiation doses D. A distortion (contraction ratio: ΔL/L) at each die is calculated, and then, a relationship between a distortion (contraction ratio) and ρD (total dose per unit area) is calculated. L indicates a substrate size, and ΔL indicates a positional deviation amount. As shown in the example of FIG. 13, the distortion (contraction ratio) increases in proportion to ρD. Therefore, the distortion (contraction ratio) can be calculated using a dose (irradiation coefficient) defined in the dose map.

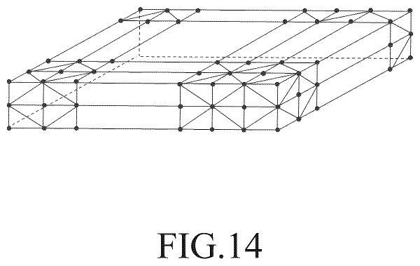

FIG. 14 is an illustration showing an example of a model by a finite element method according to the first embodiment. The example of FIG. 14 shows the state where a 6-inch mask serving as an example of the target object 101 is divided by a triangular pyramid element. One triangular pyramid element has four vertices, and each vertex has three-dimensional displacement information of displacement vector u=(uₓ, u_{y}, u_{z}). That is, variables, totally 4×3=12 variables, exist in one unit element. In a relational expression ε=Bu between displacement vector u(12×1) and strain vector ε(6×1), “strain of unit element”−“displacement matrix M₁(6×12)” is expressed by the following equation (1) as an example.

$${M}_{1} = [ \begin{matrix}- 1 & 0 & 0 & 1 & 0 & 0 & 0 & 0 & 0 & 0 & 0 & 0 \\ 0 & - 1 & 0 & 0 & 0 & 0 & 0 & 1 & 0 & 0 & 0 & 0 \\ 0 & 0 & - 1 & 0 & 0 & 0 & 0 & 0 & 0 & 0 & 0 & 1 \\ - 1 & - 1 & 0 & 0 & 1 & 0 & 1 & 0 & 0 & 0 & 0 & 0 \\ 0 & - 1 & - 1 & 0 & 0 & 0 & 0 & 0 & 1 & 0 & 1 & 0 \\ - 1 & 0 & - 1 & 0 & 0 & 1 & 0 & 0 & 0 & 1 & 0 & 0\end{matrix} ] \qquad ( 1 )$$

In a relational expression σ=Dε between stress vector σ(6×1) and strain vector ε(6×1), a material physical properties matrix M₂(6×6) of a unit element is expressed by the following equation (2) using Young's modulus E and Poisson's ratio ν of a quartz substrate.

$${M}_{2} = \frac{E}{( 1 - 2 v ) ( 1 + v )} [ \begin{matrix}1 - v & v & v & 0 & 0 & 0 \\ v & 1 - μ & v & 0 & 0 & 0 \\ v & v & 1 - v & 0 & 0 & 0 \\ 0 & 0 & 0 & \frac{1 - 2 v}{2} & 0 & 0 \\ 0 & 0 & 0 & 0 & \frac{1 - 2 v}{2} & 0 \\ 0 & 0 & 0 & 0 & 0 & \frac{1 - 2 v}{2}\end{matrix} ] \qquad ( 2 )$$

Strain e of the substrate surface generated by a charged particle beam dose Q(=ρD) is defined by the following equation (3) using coefficients c₀ and c₁.

$$e = {c}_{0} + {c}_{1} \cdot Q \qquad ( 3 )$$

Supposing that a shearing strain generated by charged particle beam irradiation is zero, strain vector ε of a unit element can be defined by the following equation (4).

$${ϵ}^{t} = \{ \begin{matrix}e & e & e & 0 & 0 & 0\end{matrix} \} \qquad ( 4 )$$

A stiffness matrix per unit element is denoted by the following equation (5).

$${B}^{t} {M}_{2}^{t} Bu = {B}^{t} {M}_{2}^{t} ε \qquad ( 5 )$$

In the equation (5), t indicates a transposed matrix. Combining all the elements in the above equations, a displacement vector U of all the vertices, a whole stiffness matrix K, and an equivalent nodal force f are defined by the following equations (6-1), (6-2), and (6-3).

$$\int ( {B}^{t} {M}_{2}^{t} B ) dV \cdot U = \int ( {B}^{t} {M}_{2}^{t} ε ) dV \qquad ( 6 - 1 )$$

$$K = \int ( {B}^{t} {M}_{2}^{t} B ) dV \qquad ( 6 - 2 )$$

$$f = \int ( {B}^{t} {M}_{2}^{t} ε ) dV \qquad ( 6 - 3 )$$

Consequently, the following equation (7) is obtained.

$$KU = f \qquad ( 7 )$$

Finally, the total displacement vector U can be obtained by the following equation (8).

$$U = {K}^{- 1} f \qquad ( 8 )$$

For calculating a final positional deviation amount (dxfinal-i, dyfinal-i) of each position, first, distortion e of each element and distortion vector ε of the equation (4) are obtained by substituting a value of an element in the dose map generated from the layout into Q of the equation (3). Then, by solving the equation (8) by calculating f of the equation (6-3) by using an obtained distortion vector ε of each element, the total displacement vector U, including displacement vector u of each element, at the time of completion of all dose irradiation for writing can be obtained. Based on displacement vector u of each element, a displacement amount (uₓ, u_{y}) of each element can be obtained as a final positional deviation amount (dxfinal-i, dyfinal-i). The obtained final positional deviation amount of each position is stored in the storage device 142.

In the writing schedule generation step (S106), the writing control unit 76 generates a writing schedule which defines the order of shot of each pixel defined in the dose map. Thereby, for each shot, positions and dose amounts having been irradiated by the time (writing time) of performing a shot concerned can be known.

In the writing-time positional deviation amount (vector B) calculation step (S108), in writing processing, the writing-time positional deviation amount calculation unit 54 calculates a writing-time positional deviation amount (the second positional deviation amount) deviated from a design pattern position because of an irreversible deformation of the target object 101 generated by electron beam irradiation onto the target object 101 having been performed before irradiation of the current electron beam. In other words, the writing-time positional deviation amount calculation unit 54 calculates a writing-time positional deviation amount (the second positional deviation amount) of a pattern formation position or a beam irradiation position deviated from its design position at the time of irradiation of an electron beam concerned because of an irreversible deformation of the target object 101 generated by electron beam irradiation onto the target object 101 having been performed before irradiation of the current electron beam concerned. Specifically, the writing-time positional deviation amount calculation unit 54 calculates a positional deviation amount (vector B) at the time of writing a representative position in each global mesh region 11. The vector B of each global mesh region 11 is calculated as a writing-time positional deviation amount (dxwrite-n, dywrite-n). n indicates the index of each global mesh region 11. The writing-time positional deviation amount of the global mesh region 11 where a pattern formation position or a beam irradiation position is included corresponds to the writing-time positional deviation amount of the formation position of the pattern concerned or the beam irradiation position. The writing-time positional deviation amount (dxwrite-n, dywrite-n) of each global mesh region 11 depends on a dose (irradiation coefficient) defined in the dose map, and, as described above, can be similarly calculated using a finite element method, for example. Specifically, by substituting a dose of each element at the time of completion of irradiation of up to the n-th dose in the doses defined in the dose map into Q of the equation (3), distortion e of each element and distortion vector ε of the equation (4) are obtained. Then, by solving the equation (8) by calculating f of the equation (6-3) by using an obtained distortion vector C of each element, the total displacement vector U, including displacement vector u of each element, at the time of completion of irradiation of up to the n-th dose can be obtained. Based on displacement vector u of each element, a displacement amount (uₓ, u_{y}) of each element can be obtained as a writing-time positional deviation amount (dxwrite-n, dywrite-n).

In the example described above, a writing-time positional deviation amount is calculated for each global mesh region 11. However, it is not limited thereto. It is also preferable to calculate a writing-time positional deviation amount for each representative position (e.g., center position or position of center beam) of a beam array at the time of an actual shot.

In the correction amount calculation step (S110), based on a final positional deviation amount, the correction amount calculation unit 56 calculates a correction amount (vector B−vector C) (the first correction amount) for correcting a pattern position or an electron beam irradiation position when forming a pattern by applying an electron beam to the target object 101. In other words, based on a final positional deviation amount due to an irreversible deformation of the target object 101 after completion of writing, the correction amount calculation unit 56 calculates a correction amount (vector B−vector C) (the first correction amount) for correcting a pattern formation position or a beam irradiation position in the case of applying the multiple beams 20 (electron beam) to the target object 101. The correction amount (vector B−vector C) (the first correction amount) is calculated as a difference between the writing-time positional deviation amount (vector B) and the final positional deviation amount (vector C). In other words, the correction amount (dxn, dyn) of each position in the n-th beam-irradiated (written) global mesh region 11 can be calculated by a subtraction of “the writing-time positional deviation amount (dxwrite-n, dywrite-n)”−“the final positional deviation amount (dxfinal-n, dyfinal-n)”.

The correction amount map generation unit 58 generates a correction amount map in which a correction amount (dxn, dyn) is defined for each global mesh region (xn, yn). The correction amount map is stored in the storage device 142.

When processing up to calculating the correction amount per stripe region unit has been completed, it proceeds to the writing step (S170) in a real time mode.

FIG. 15 is a conceptual diagram showing an example of a writing operation according to the first embodiment. As shown in FIG. 15, a writing region 30 (bold line) of the target object 101 is defined based on the position of an alignment mark 14. The writing region 30 (bold line) is virtually divided into a plurality of stripe regions 32 by a predetermined width in the y direction, for example. In the case of FIG. 15, the writing region 30 of the target object 101 is divided into a plurality of stripe regions 32 by the width size being substantially the same as the design size of an irradiation region 34 (beam array region) which can be irradiated by one irradiation with the multiple beams 20. The x-direction design size of the irradiation region 34 of the multiple beams 20 can be defined by (the number of x-direction beams)×(x-direction beam pitch). The y-direction size of the rectangular irradiation region 34 can be defined by (the number of y-direction beams)×(y-direction beam pitch).

First, the XY stage 105 is moved to make an adjustment such that the irradiation region 34 of the multiple beams 20 is located at the left end, or at a position further left than the left end, of the first stripe region 32, and then writing of the first stripe region 32 is performed. When writing the first stripe region 32, the XY stage 105 is moved, for example, in the −x direction, so that the writing may relatively proceed in the x direction. The XY stage 105 is moved, for example, continuously at a constant speed. After writing the first stripe region 32, the stage position is moved in the −y direction by the width of the stripe region 32.

Next, an adjustment is made such that the irradiation region 34 of the multiple beams 20 is located at the left end, or at a position further left than the left end, of the second stripe region 32. Then, writing of the second stripe region 32 is performed by moving the XY stage 105, for example, in the −x direction to proceed the writing relatively in the x direction. Henceforth, similarly, writing is performed in the y direction in order from the stripe region 32 at the lower side to the upper side.

FIG. 15 shows the case where respective stripe regions 32 are written in the same direction, but, it is not limited thereto. For example, with respect to the stripe region 32 to be written following the stripe region 32 having been written in the x direction, it may be written in the −x direction by moving the XY stage 105 in the x direction, for example. Thus, the stage moving time can be reduced by performing writing while alternately changing the writing direction, which results in reducing the writing time. A plurality of shot patterns maximally up to as many as the number of the holes 22 are formed at a time by one shot of multiple beams 20 having been formed by individually passing through the holes 22 in the shaping aperture array substrate 203.

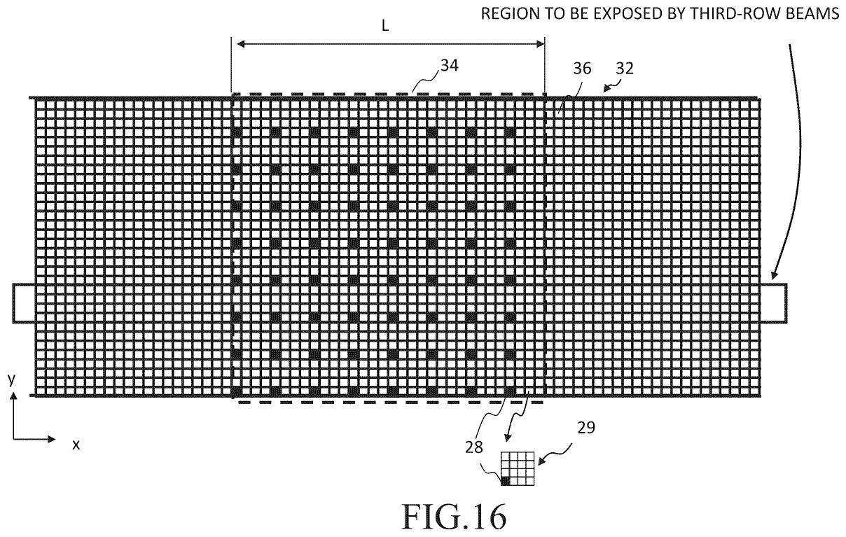

FIG. 16 is an illustration showing an example of an irradiation region of multiple beams and a pixel to be written (writing target pixel) according to the first embodiment. In FIG. 16, the stripe region 32 is divided into a plurality of mesh regions by the beam size of the multiple beams 20, for example. Each mesh region serves as a writing target pixel 36 (unit irradiation region, irradiation position, or writing position). The size of the writing pixel 36 is not limited to the beam size, and may be any size regardless of the beam size. For example, it may be 1/n (n being an integer of 1 or more) of the beam size. FIG. 16 shows the case where the writing region of the target object 101 is divided, for example, in the y direction, into a plurality of stripe regions 32 by the width size being substantially the same as the size of the irradiation region 34 (writing field) which can be irradiated by one irradiation of the multiple beams 20. The x-direction size of the rectangular, including square, irradiation region 34 can be defined by (the number of x-direction beams)×(beam pitch in the x direction). The y-direction size of the rectangular irradiation region 34 can be defined by (the number of y-direction beams)×(beam pitch in the y direction). FIG. 16 shows the case of multiple beams of 512×512 (rows×columns) being simplified to 8×8 (rows×columns). In the irradiation region 34, there are shown a plurality of pixels 28 (beam writing positions) which can be irradiated with one shot of the multiple beams 20. The pitch between adjacent pixels 28 is the beam pitch of the multiple beams. A sub-irradiation region 29 (pitch cell) is configured by a rectangular, including square, region surrounded by the size of beam pitches in the x and y directions. In the example of FIG. 16, each sub-irradiation region 29 is composed of 4×4 pixels, for example.

In the writing step (S170), the shot data generation unit 70 calculates, for each pixel 36, an incident dose D(x) (amount of dose) with which the pixel 36 concerned is irradiated. The incident dose D(x) can be calculated, for example, by multiplying a base dose D_{base} by a proximity effect correction irradiation coefficient Dp and a pattern area density ρ′. The base dose D_{base} can be defined by Dth/(½+r), for example. Thereby, it is possible to obtain an incident dose D(x) for each pixel 36, for which a proximity effect has been corrected, based on layout of a plurality of figure patterns defined by the writing data. In other words, the incident dose D(x) (amount of dose) is calculated by multiplying the dose defined in the dose map by the base dose D_{base}. If the incident dose D(x) (amount of dose) is defined in the dose map, it may be used as it is.

Next, the shot data generation unit 70 calculates an irradiation time for each pixel 36. The irradiation time for each pixel 36 can be obtained by diving an incident dose D(x) of a pixel concerned by a current density J.

The data processing unit 72 rearranges obtained irradiation time data for each pixel 36 in the order of shot, and stores it in the storage device 142. The transmission processing unit 74 transmits, in the order of shot, the irradiation time data to the deflection control circuit 130.

Under the control of the writing control unit 76, the writing mechanism 150 writes a pattern on the target object 101 with the multiple beams 20 (electron beam), based on the beam irradiation position corrected by the correction amount. In other words, the writing mechanism 150 corrects, based on the final positional deviation amount, a pattern position or an electron beam irradiation position when forming a pattern by applying an electron beam to the target object 101, and performs writing processing to write a pattern on the target object 101. The writing mechanism 150 performs correction based on a difference between the writing-time positional deviation amount and the final positional deviation amount. The writing mechanism 150 performs writing while moving the XY stage 105. Specifically, under the control of the deflection control circuit 130 (an example of a correction unit), for each tracking cycle of the multiple beams 20 described later, the deflector 208 deflects a beam array (irradiation region) to a position corrected by a correction amount (dxn, dyn) of the global mesh region 11 where a representative position (e.g., center position or center beam position) of the beam array is included. The deflection position of the beam array (irradiation region 34) is set based on the representative position (for example, a center position or center beam position) of the beam array described above.

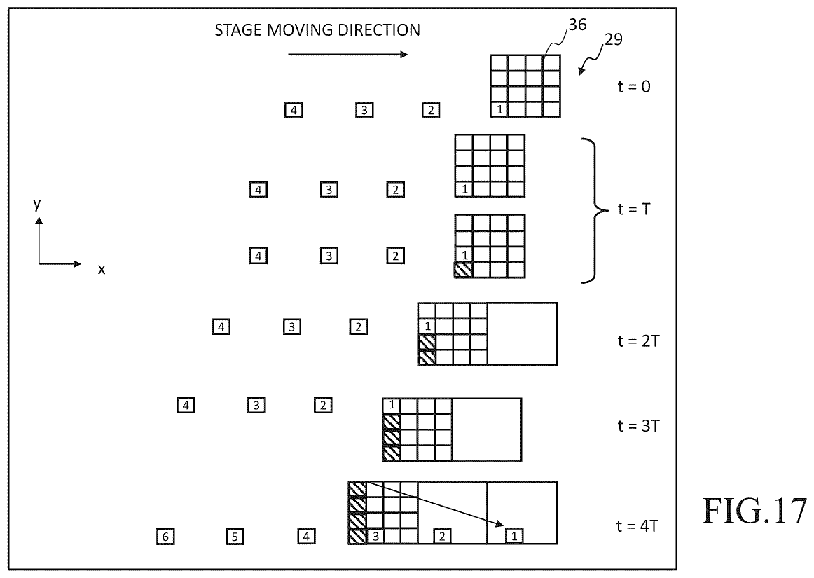

FIG. 17 is an illustration explaining an example of a multi-beam writing operation according to the first embodiment. FIG. 17 shows the case where the inside of each sub-irradiation region 29, which includes the beam irradiation position of one of the multiple beams 20 and is surrounded with the beam pitch (pitch between beams), is written with four different beams. The example of FIG. 17 shows a writing operation where the XY stage 105 continuously moves at the speed at which the XY stage 105 moves the distance of two beam pitches, for example, while a ¼ region, namely the region of 1/(the number of beams used for irradiation), in each sub-irradiation region 29 is written. FIG. 17 shows the case where each sub-irradiation region 29 is composed of 4×4 pixels, for example.

In the writing operation shown in FIG. 17, for example, while the XY stage 105 moves the distance of two beam pitches in the x direction, four pixels 36 in the same sub-irradiation region 29 are written (exposed) by applying four shots of the multiple beams 20 at a shot cycle T with shifting the irradiation position (pixel 36) in order by the deflector 209. In order that the relative position between the irradiation region 34 and the target object 101 may not be displaced by the movement of the XY stage 105 while these four pixels 36 are written (exposed), the irradiation region 34 is made to follow the movement of the XY stage 105 by collective deflection of all of the multiple beams 20 by the deflector 208. In other words, a tracking control is performed. In the example of FIG. 17, although the time period during which the XY stage 105 moves the distance of two beam pitches in the x direction 2 is described as an example of a tracking cycle, it is not limited thereto. A time period during which the XY stage 105 moves the distance larger than the distance of two beam pitches, such as the distance of eight beam pitches or the distance of sixteen beam pitches may also be used.

After one tracking cycle is completed, tracking is reset to return to the previous (last) tracking starting position. Since writing of the pixels in the first column from the left of each sub-irradiation region 29 has been completed, in the next tracking cycle after resetting the tracking, first, the deflector 209 provides deflection such that the writing position of a beam which is different from that used for the first pixel column is adjusted (shifted) to write the second pixel column from the left still not having been written in each sub-irradiation region 29, for example. By repeating this operation during writing the stripe region 32, as shown in the lower part of FIG. 15, the position of the irradiation region 34 (34a to 34o) of the multiple beams 20 is sequentially moved (shifted) to perform writing.

Therefore, under the control of the deflection control circuit 130, the deflector 208 deflects, in each tracking cycle, a beam array to a position corrected by a correction amount (dxn, dyn) of the global mesh region 11 where a representative position (e.g., center position or center beam position) of the beam array is included. During the tracking cycle, at that position, while each beam writes (exposes), for example, four pixels 36, the beam array (irradiation region 34) is made to follow the movement of the XY stage 105 by collectively deflecting all of the multiple beams 20 by the deflector 208 in order that the relative position between the beam array (irradiation region 34) and the target object 101 may not be displaced by the movement of the XY stage 105.

As shown in the lower part of FIG. 15, the position of the irradiation region 34 (34a to 34o) of the multiple beams 20 moves gradually. Therefore, there is a case where shot of the multiple beams 20 is performed in the state of the irradiation region 34 (beam array) extending over adjacent global mesh regions 11. Including such a case, the correction amount (dxn, dyn) of the global mesh region 11 where a representative position (for example, a center position or center beam position) of the irradiation region 34 (beam array) is included can be used.

In the real time mode shown in FIG. 11, while performing writing processing, shot data of the stripe region 32 to be subsequently written is generated in parallel. For example, while writing the k-th stripe region 32, shot data for the (k+2)th stripe region 32 is generated in parallel.

In the determination step (S172), the writing control unit 76 determines whether writing of all the stripe regions 32 has been completed. When not completed, it returns to the writing-time positional deviation amount calculation step (S108), and, with respect to the next stripe region 32, steps from the writing-time positional deviation amount calculation step (S108) to the determination step (S172) are repeated. Thus, steps from the writing-time positional deviation amount calculation step (S108) to the determination step (S172) are repeated until writing of all the stripe regions 32 has been completed.

In the preprocessing mode shown in FIG. 12, with respect to each stripe region 32, as the determination step (S112) after carrying out the correction amount calculation step (S110), the writing control unit 76 determines whether calculation of the correction amount has been completed for all the stripe regions 32. When not completed, it returns to the writing-time positional deviation amount calculation step (S108), and, with respect to the next stripe region 32, steps from the writing-time positional deviation amount calculation step (S108) to the determination step (S112) are repeated. Thus, steps from the writing-time positional deviation amount calculation step (S108) to the determination step (S112) are repeated until writing of all the stripe regions 32 has been completed.

In the correction amount map generation step (S114), the correction amount map generation unit 58 generates, with respect to the whole surface of the target object 101, a correction amount map whose element value is a correction amount of each global mesh region 11.

In the writing step (S170), the writing mechanism 150 writes a pattern on the target object 101 with the multiple beams 20 (electron beam), based on the beam irradiation position corrected by using the correction amount. The contents of the writing step (S170) are the same as those in the real time mode. However, since the correction amount map of the whole region of the target object 101 has already been generated, it is not necessary to calculate a correction amount while writing. What is necessary is to write each stripe region 20 sequentially.

Although, in the examples described above, the deflection position (beam irradiation position) of a beam array is corrected using a correction amount, the method of correction is not limited thereto. Henceforth, a modified example of the first embodiment will be described.

In the modified example of the first embodiment, the shot data generation unit 70, first, corrects a pattern formation position in the writing data, based on a correction amount map. Specifically, it operates as follows: The shot data generation unit 70 corrects, for each global mesh region 11, the position of a pattern included in the global mesh region 11 concerned by a correction amount defined for the global mesh region 11 concerned.

Then, the shot data generation unit 70 newly generates a dose map by using a corrected pattern layout. The contents of the method of generating a dose map is the same as those described above. The shot data generation unit 70 calculates an irradiation time for each pixel 36. The irradiation time for each pixel 36 can be calculated by dividing an incident dose D(x) of a pixel concerned by a current density J.

The data processing unit 72 rearranges obtained irradiation time data for each pixel 36 in the order of shot, and stores it in the storage device 142. The transmission processing unit 74 transmits the irradiation time data to the deflection control circuit 130 in the order of shot.

Under the control of the writing control unit 76, the writing mechanism 150 writes a pattern on the target object 101 with the multiple beams 20 (electron beam), based on the beam irradiation position corrected by the correction amount. In the modified example of the first embodiment, in both the real time mode and the preprocessing mode, the position of a pattern has already been corrected by the correction amount (dxn, dyn) in pattern data. Therefore, in performing writing, under the control of the deflection control circuit 130, the deflector 208 deflects, in each tracking cycle, a representative position (e.g., center position or center beam position) of the beam array to its design position, and during the tracking cycle, at that position, while each beam writes (exposes), for example, four pixels 36, the beam array (irradiation region 34) is made to follow the movement of the XY stage 105 by collectively deflecting all of the multiple beams 20 by the deflector 208 in order that the relative position between the beam array (irradiation region 34) and the target object 101 may not be displaced by the movement of the XY stage 105.

In the first embodiment described above, writing processing is performed once (one time) with respect to the target object 101. Such one-time writing processing indicates a process from starting writing to completing writing processing for the whole writing region (chip region) of the target object 101. Therefore, such processing may include, for example, multiple writing in which, while shifting the position in the y direction per stripe region such that a portion of stripe regions overlap each other, multiple writing on the overlapped portion is repeated, or multiple writing in which, during one-time stripe writing for each stripe region 20, the region having been written by beams arrayed in the front side with respect to the writing direction in the multiple beams 20 is repeatedly written by beams arrayed in the back side with respect to the writing direction in the multiple beams 20. For example, in a case where the target object 101 is rewritten such that the beam array moves relatively to the right, the right half of the beam array is the front side with respect to the writing direction, and the left half is the back side to the writing direction.

As described above, according to the first embodiment, it is possible to correct a positional deviation of the beam irradiation position and pattern formation position deviated because of an irreversible deformation of the target object 101 due to irradiation of the multiple beams 20 (electron beam).

### Second Embodiment

A second embodiment describes the case of two-stroke writing where, after writing processing for the whole writing region (chip region) of the target object 101 is completed, writing processing for the whole writing region (chip region) of the target object 101 is performed again using the same layout pattern.

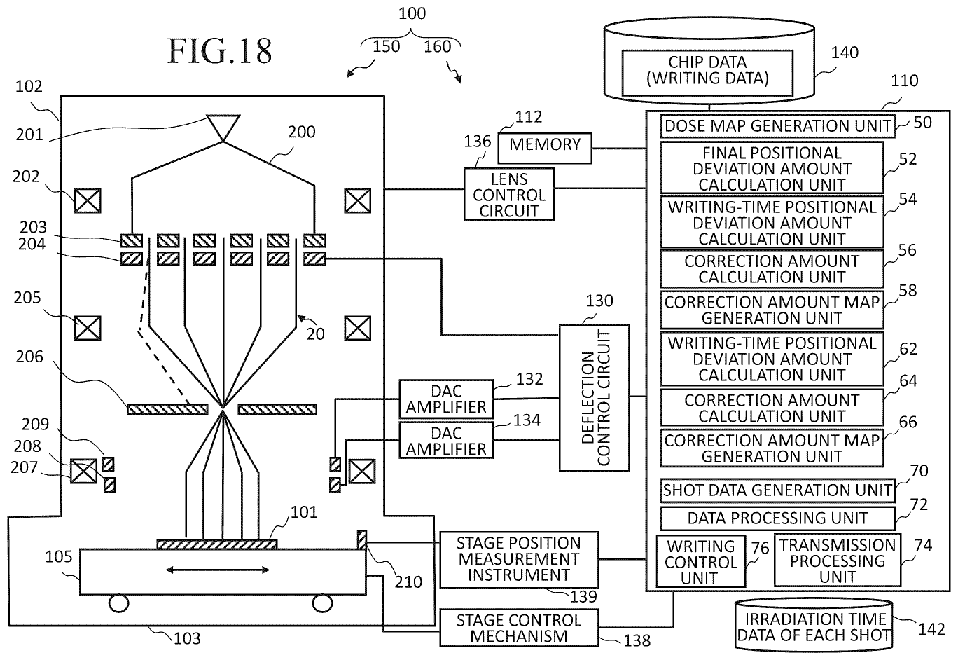

FIG. 18 is a conceptual diagram showing a configuration of a writing apparatus according to the second embodiment. FIG. 18 is the same as FIG. 1 except that a writing-time positional deviation amount calculation unit 62, a correction amount calculation unit 64, and a correction amount map generation unit 66 are further added in the control computer 110. Each of the “ . . . units” such as the dose map generation unit 50, the final positional deviation amount calculation unit 52, the writing-time positional deviation amount calculation unit 54, the correction amount calculation unit 56, the correction amount map generation unit 58, the writing-time positional deviation amount calculation unit 62, the correction amount calculation unit 64, the correction amount map generation unit 66, the shot data generation unit 70, the data processing unit 72, the transmission processing unit 74, and the writing control unit 76 includes processing circuitry. The processing circuitry includes, for example, an electric circuit, a computer, a processor, a circuit board, a quantum circuit, a semiconductor device, or the like. Each “ . . . unit” may use common processing circuitry (the same processing circuitry), or different processing circuitry (separate processing circuitry). Information input/output to/from the dose map generation unit 50, the final positional deviation amount calculation unit 52, the writing-time positional deviation amount calculation unit 54, the correction amount calculation unit 56, the correction amount map generation unit 58, the writing-time positional deviation amount calculation unit 62, the correction amount calculation unit 64, the correction amount map generation unit 66, the shot data generation unit 70, the data processing unit 72, the transmission processing unit 74, and the writing control unit 76, and information being operated are stored in the memory 112 each time. It is acceptable that one of the writing-time positional deviation amount calculation unit 54 and the writing-time positional deviation amount calculation units 62 has both the functions of them. In that case, the other one may be omitted.

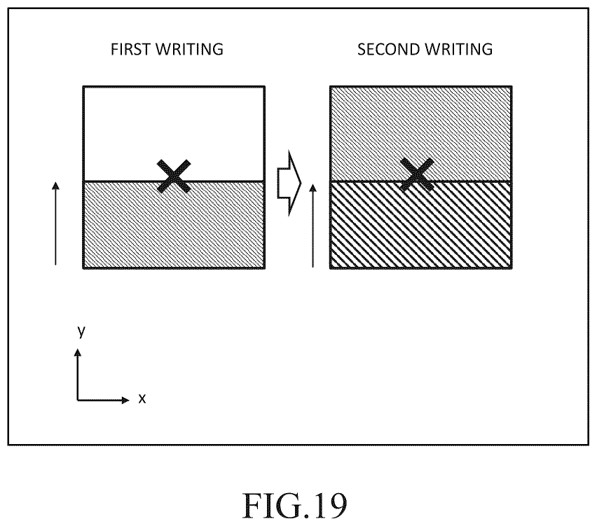

FIG. 19 is an illustration explaining a method of two-stroke writing according to the second embodiment. In FIG. 19, in the first writing processing (the first stroke), writing is performed in the y direction in order from the stripe region 32 at the lower side to the upper side of the target object 101. The left illustration of FIG. 19 shows a state of writing a certain position (denoted by x) in the middle of the first writing processing. Then, after the first writing processing for the whole writing region (chip region) of the target object 101, with maintaining the target object 101 placed on the stage 105, the second writing processing (the second stroke) of repeating writing by using the writing data of the same pattern layout is performed. The right illustration of FIG. 19 shows a state of writing a certain position (denoted by x, which is the same position as that in the left side) in the middle of the second writing processing.

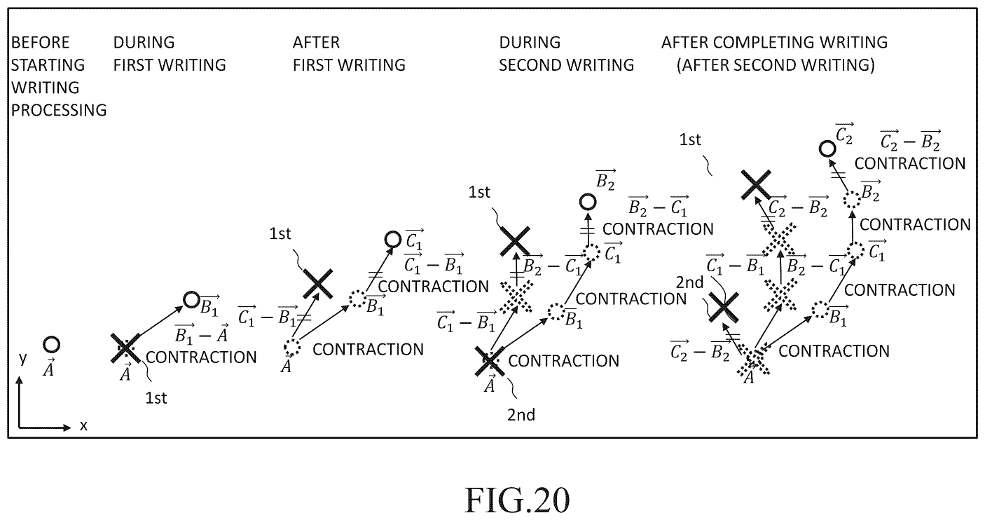

FIG. 20 is an illustration showing an example of a positional deviation state of a substrate surface according to a comparative example of the second embodiment. FIG. 20 shows a state before starting the first writing processing, a state during writing at a desired position in the first writing processing, a state after completing the first writing processing, a state during writing at a desired position in the second writing processing, and a state after completing the second writing process.

In FIG. 20, the vector A indicates a design beam irradiation position. While the first writing processing proceeds for the target LTEM substrate, at the time of writing the position of the vector A in the first writing processing, the position of the vector A before starting writing processing has physically moved to the position of the vector B₁ because a deformation due to contraction of the substrate occurred as shown in FIG. 20. Then, along with the writing processing further proceeds, at the time of completion of the first writing processing, the position of the vector A before starting writing processing has physically moved to the position of the vector C₁ because of a further deformation as shown in FIG. 20. Then, starting the second writing processing, along with the writing processing proceeds, at the time of writing the position of the vector A in the second writing processing, the position of the vector A before starting writing processing has physically moved to the position of the vector B₂ because of a deformation due to contraction of the substrate as shown in FIG. 20. Along with the writing processing further proceeds, at the time of completion of the second writing processing (after completing writing processing for the whole substrate), the position of the vector A before starting writing processing has physically moved to the position of the vector C₂ because of a further deformation as shown in FIG. 20.

Therefore, if the position of the vector A before staring writing processing is written as it is in the first writing processing, at the time of completion of the writing processing for the whole substrate, the written beam irradiation position has deviated, by a vector of (vector C₂-vector B₁), from the position of the vector A before starting writing processing to the moved position (vector A+(vector C₂-vector B₁)). Similarly, if the position of the vector A before starting writing processing is written as it is in the second writing processing, at the time of completion of the writing processing of the whole substrate, the written beam irradiation position has deviated, by a vector of (vector C₂−vector B₂), from the position of the vector A before starting writing processing to the moved position (vector A+(vector C₂−vector B₂)). Then, according to the second embodiment, the writing-time irradiation position (pattern formation position) is corrected in order to let the beam irradiation position after completion of the writing processing be the position of the vector A before starting writing processing, even in the case of an irreversible deformation occurring in the substrate.

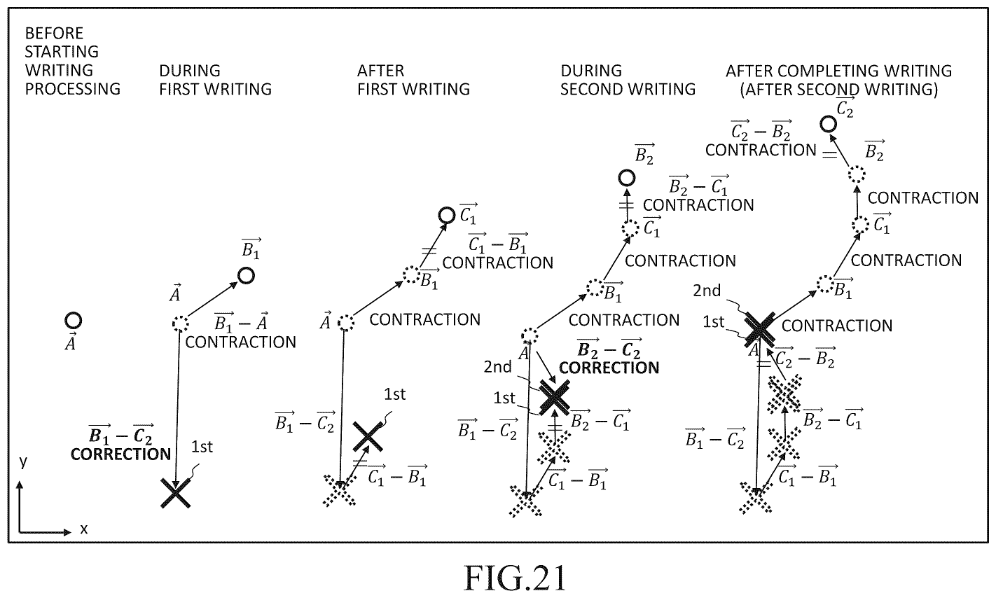

FIG. 21 is an illustration showing an example of a positional deviation state of a substrate surface according to the second embodiment. The state of deformation of the substrate surface of the second embodiment is not illustrated. In FIG. 21, the vector A indicates a design beam irradiation position. While the first writing processing proceeds for the target LTEM substrate, at the time of writing the position of the vector A in the first writing processing, the position of the vector A before starting writing processing has physically moved to the position of the vector B₁ because a deformation due to contraction of the substrate occurred as shown in FIG. 21. Then, after completing the first writing processing, and further after completing the second writing processing, that is at the time of completion of writing the whole substrate, the position of the vector A before starting writing processing has physically moved to the position of the vector C₂ because of a further deformation as shown in FIG. 21.

Therefore, when writing in the first writing processing, it is sufficient to perform correction to be corrected by the positional deviation amount (vector C₂−vector B₁) which is from the position (vector B₁) at that time to the position (vector C₂) after completion writing processing for the whole substrate. Therefore, at the time of writing in the first writing processing, the position corrected, by a vector of (vector B₁−vector C₂), from the position of the vector A before starting writing processing to a corrected position (vector A+(vector B₁−vector C₂)) is written as a beam irradiation position (or pattern formation position). Thereby, after the second writing processing, that is after completing writing processing for the whole substrate, the beam irradiation position (or pattern formation position) written in the first writing processing can be the position of the vector A being the position moved from the position (vector A+(vector B₁−vector C₂)) by a vector of (vector C₂−vector B₁).

At the time of writing the position of the vector A in the second writing processing, the position of the vector A before starting writing processing has physically moved to the position of the vector B₂ because a deformation due to contraction of the substrate occurred as shown in FIG. 21. After completion of the second writing processing, that is after completion of the writing processing for the whole substrate, the position of the vector A before starting writing processing has physically moved to the position of the vector C₂ as described above.

Therefore, when writing in the second writing processing, it is sufficient to perform correction to be corrected by the positional deviation amount (vector C₂−vector B₂) which is from the position (vector B₂) at that time to the position (vector C₂) after completing writing processing for the whole substrate. Therefore, at the time of writing in the second writing processing, the position corrected, by a vector of (vector B₂−vector C₂), from the position of the vector A before starting writing processing to a corrected position (vector A+(vector B₂−vector C₂)) is written as a beam irradiation position (or pattern formation position). Thereby, after the second writing processing, that is after completing writing processing for the whole substrate, the beam irradiation position (or pattern formation position) written in the second writing processing can be the position of the vector A being the position moved from the position (vector A+(vector B₂−vector C₂)) by a vector of (vector C₂−vector B₂).

Accordingly, when completing writing processing for the whole substrate, both of the beam irradiation position written in the first writing processing and the beam irradiation position written in the second writing processing can be the position of the vector A before starting writing processing.

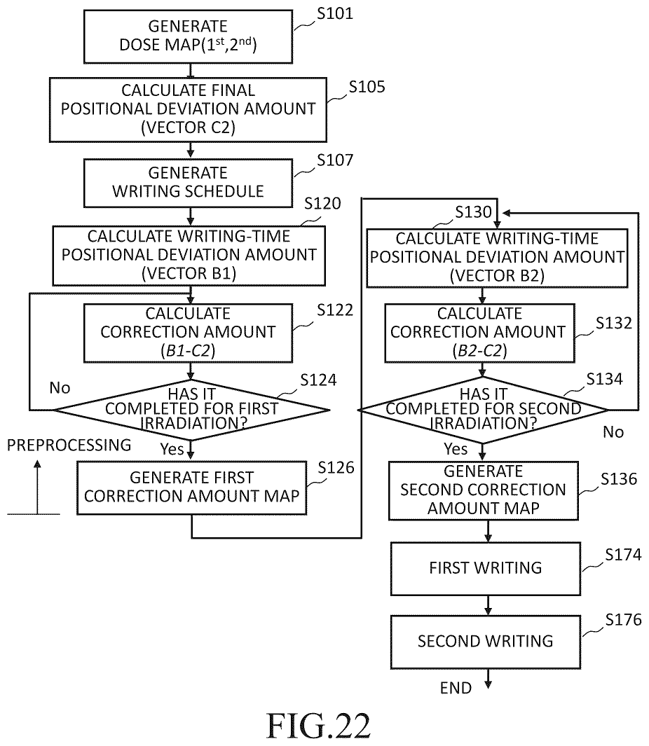

FIG. 22 is a flowchart showing an example of main steps of a writing method according to the second embodiment. In FIG. 22, the writing method of the second embodiment executes a series of steps: a dose map generation step (S101), a final positional deviation amount (vector C₂) calculation step (S105), a writing schedule generation step (S107), a writing-time positional deviation amount (vector B₁) calculation step (S120), a correction amount calculation step (S122), a determination step (S124), a first correction amount map generation step (S126), a writing-time positional deviation amount (vector B₂) calculation step (S130), a correction amount calculation step (S132), a determination step (S134), a second correction amount map generation step (S136), a first writing step (S174), and a second writing step (S176). The writing processing according to the second embodiment includes the first writing processing which writes the first chip pattern, and the second writing processing which is performed after the first writing processing and writes the second chip pattern to be superimposed (overlapped) on the first chip pattern. In the second embodiment, the second chip pattern is the same as the first chip pattern.

FIG. 22 shows a flowchart in the case where writing processing is performed in a pre-processing mode of starting a writing operation after performing a calculation process, as a pre-process, for correcting beam irradiation positions (or pattern formation positions) in all the regions. It is omitted to show a flowchart of performing writing processing in a real-time mode of executing a calculation process for correcting a beam irradiation position (or pattern formation position) in the next region while performing a writing operation.

In a real-time mode, the writing operation for the k-th stripe region in the first writing processing, the correction calculation processing (writing-time positional deviation amount (vector B₁) calculation step (S120)) of the (k+m)th stripe region, the correction amount calculation step (S122), the determination step (S124), and the first correction amount map generation step (S126) are carried out at the same period. Then, with respect to the stripe region 32 for which the correction calculation processing has been completed, the first writing step (S174) is performed sequentially. Similarly, the writing operation of the k-th stripe region in the second writing processing, the correction calculation processing (writing-time positional deviation amount (vector B₂) calculation step (S130)) of the (k+m)th stripe region, the correction amount calculation step (S132), the determination step (S134), and the second correction amount map generation step (S136) are carried out at the same period. Then, with respect to the stripe region 32 for which the correction calculation processing has been completed, the second writing step (S176) is performed sequentially.

In the dose map generation step (S101), the dose map generation unit 50 generates a dose map in which a dose is defined for each pixel. Here, the dose map generation unit 50 generates a dose map (the first dose map) for the first writing processing and a dose map (the second dose map) for the second writing processing. Since writing processing using the same layout pattern is performed two strokes, the dose incident on each pixel is divided into halves, for example. In such a case, generally, the first dose map and the second dose map are the same as each other. The method of generating a dose map may be the same as that of the dose map generation step (S102) described above.

In the final positional deviation amount (vector C₂) calculation step (S105), in the case of writing a pattern with electron beams on the target object 101 which irreversibly deforms due to electron beam irradiation, the final positional deviation amount calculation unit 52 calculates a final positional deviation amount (the first positional deviation amount) of a pattern formation position or beam irradiation position deviated from its design position because of an irreversible deformation of the target object 101 after completion of the writing processing. Specifically, the final positional deviation amount calculation unit 52 calculates a positional deviation amount (vector C₂) of each position after the first and second writing processing has completed, and, that is, after completion of the writing processing to the target object 101. In other words, the final positional deviation amount is a positional deviation amount from a design pattern position due to an irreversible deformation of the target object 101 after completion of the second writing processing.

The final positional deviation amount calculation unit 52 calculates the vector C₂ at a representative point (e.g., center position) in each global mesh region 11 (position). Each vector C₂ is calculated as a final positional deviation amount (dxfinal-i, dyfinal-i). i indicates the index of each global mesh region 11. The final positional deviation amount of the global mesh region 11 where a pattern formation position or a beam irradiation position is included corresponds to the final positional deviation amount of the formation position of the pattern concerned or the beam irradiation position. The final positional deviation amount (dxfinal-i, dyfinal-i) of each global mesh region 11 is depending on a dose (irradiation coefficient) defined in the dose map, and can be calculated using a finite element method as described above.

In the writing schedule generation step (S107), the writing control unit 76 generates a writing schedule which defines the order of shot of each pixel defined in the dose map. Here, a writing schedule is generated for each of the first writing processing and the second writing processing. Thereby, for each shot, positions and dose amounts having been irradiated by the time (writing time) of performing a shot concerned can be known.

In the writing-time positional deviation amount (vector B₁) calculation step (S120), in the first writing processing, the writing-time positional deviation amount calculation unit 54 calculates a writing-time positional deviation amount (the second positional deviation amount) deviated from a design position because of an irreversible deformation of the target object 101 generated by electron beam irradiation onto the target object 101 having been performed before irradiation of the current electron beam. In other words, the writing-time positional deviation amount calculation unit 54 calculates a writing-time positional deviation amount (the second positional deviation amount) of a pattern formation position or a beam irradiation position deviated from its design position at the time of irradiation of an electron beam concerned in the first writing processing, because of an irreversible deformation of the target object 101 generated by electron beam irradiation onto the target object 101 having been performed before irradiation of the current electron beam concerned in the first writing processing. Specifically, the writing-time positional deviation amount calculation unit 54 calculates a positional deviation amount (vector B₁) at the time of writing a representative position in each global mesh region 11. The vector B₁ of each global mesh region 11 is calculated as a writing-time positional deviation amount (dx1stwrite-n, dy1stwrite-n). n indicates the index of each global mesh region 11. The writing-time positional deviation amount of the global mesh region 11 where a pattern formation position or a beam irradiation position is included corresponds to the writing-time positional deviation amount of the formation position of the pattern concerned or the beam irradiation position. The writing-time positional deviation amount (dx1stwrite-n, dy1stwrite-n) of each global mesh region 11 depends on a dose (irradiation coefficient) defined in the dose map, and, as described above, can be similarly calculated using a finite element method, for example.

In the example described above, a writing-time positional deviation amount is calculated for each global mesh region 11. However, it is not limited thereto. It is also preferable to calculate a writing-time positional deviation amount for each representative position (e.g., center position or position of center beam) of a beam array at the time of an actual shot.

In the correction amount calculation step (S122), based on a final positional deviation amount due to an irreversible deformation of the target object 101 after completion of writing, the correction amount calculation unit 56 calculates a correction amount (vector B₁−vector C₂) (the first correction amount) for correcting a pattern formation position or a beam irradiation position in the case of applying an electron beam (the multiple beams 20) concerned to the target object 101 in the first writing processing. The correction amount (vector B₁−vector C₂) (the first correction amount) is calculated as a difference between the writing-time positional deviation amount (vector B₁) in the first writing processing and the final positional deviation amount (vector C₂). In other words, based on a difference between the writing-time positional deviation amount in the first writing processing and the final positional deviation amount, the correction amount calculation unit 56 calculates the first correction amount in the first writing processing. Further, in other words, the correction amount (dx1stn, dy1stn) of each position in the n-th beam-irradiated (written) global mesh region 11 can be calculated by a subtraction of “the writing-time positional deviation amount (dx1stwrite-n, dy1stwrite-n)”−“the final positional deviation amount (dxfinal-n, dyfinal-n)”.

In the determination step (S124), the writing control unit 76 determines whether calculation of the correction amount with respect to all the stripe regions 32 for the first writing processing has been completed. When not completed, it returns to the writing-time positional deviation amount calculation step (S120), and, with respect to the next stripe region 32, steps from the writing-time positional deviation amount calculation step (S120) to the determination step (S124) are repeated. Thus, steps from the writing-time positional deviation amount calculation step (S120) to the determination step (S124) are repeated until writing of all the stripe regions 32 has been completed.

In the first correction amount map generation step (S126), the correction amount map generation unit 58 generates, with respect to the whole surface of the target object 101, the first correction amount map whose element value is a correction amount (dx1stn, dy1stn) for the first writing processing for each global mesh region 11 (xn, yn). The first correction amount map is stored in the storage device 142.

In the writing-time positional deviation amount (vector B₂) calculation step (S130), in the second writing processing, the writing-time positional deviation amount calculation unit 62 calculates a writing-time positional deviation amount (the third positional deviation amount) deviated from a design position because of an irreversible deformation of the target object 101 generated by electron beam irradiation onto the target object 101 having been performed before irradiation of the current electron beam. In other words, the writing-time positional deviation amount calculation unit 62 calculates a writing-time positional deviation amount (the third positional deviation amount) of a pattern formation position or a beam irradiation position deviated from its design position at the time of irradiation of an electron beam in the second writing processing corresponding to the electron beam concerned in the first writing processing, deviated because of an irreversible deformation of the target object 101 generated by electron beam irradiation onto the target object 101 having been performed before irradiation of the current electron beam concerned in the second writing processing corresponding to the electron beam concerned in the first writing processing. Specifically, the writing-time positional deviation amount calculation unit 62 calculates a positional deviation amount (vector B₂) at the time of writing a representative position in each global mesh region 11. The vector B₂ of each global mesh region 11 is calculated as a writing-time positional deviation amount (dx2ndwrite-n, dy2ndwrite-n). n indicates the index of each global mesh region 11. The writing-time positional deviation amount of the global mesh region 11 where a pattern formation position or a beam irradiation position is included corresponds to the writing-time positional deviation amount of the formation position of the pattern concerned or the beam irradiation position. The writing-time positional deviation amount (dx2ndwrite-n, dy2ndwrite-n) of each global mesh region 11 depends on a dose (irradiation coefficient) defined in the dose map, and, as described above, can be similarly calculated using a finite element method, for example.

As described above, it is also preferable to calculate a writing-time positional deviation amount for each representative position (e.g., center position or position of center beam) of a beam array at the time of an actual shot.

In the correction amount calculation step (S132), based on a final positional deviation amount due to an irreversible deformation of the target object 101 after completion of writing, the correction amount calculation unit 64 calculates a correction amount (vector B₂−vector C₂) (the second correction amount) for correcting a pattern formation position or a beam irradiation position in the case of applying an electron beam (the multiple beams 20) to the target object 101 in the second writing processing corresponding to the electron beam concerned in the first writing processing. The correction amount (vector B₂−vector C₂) (the second correction amount) is calculated as a difference between the writing-time positional deviation amount (vector B₂) in the second writing processing and the final positional deviation amount (vector C₂). In other words, based on a difference between the writing-time positional deviation amount in the second writing processing and the final positional deviation amount, the correction amount calculation unit 64 calculates the second correction amount in the second writing processing. Further, in other words, the correction amount (dx2ndn, dy2ndn) of each position in the n-th beam-irradiated (written) global mesh region 11 can be calculated by a subtraction of “the writing-time positional deviation amount (dx2ndwrite-n, dy2ndwrite-n)”−“the final positional deviation amount (dxfinal-n, dyfinal-n)”.

In the determination step (S134), the writing control unit 76 determines whether calculation of the correction amount with respect to all the stripe regions 32 for the second writing processing has been completed. When not completed, it returns to the writing-time positional deviation amount calculation step (S130), and, with respect to the next stripe region 32, steps from the writing-time positional deviation amount calculation step (S130) to the determination step (S134) are repeated. Thus, steps from the writing-time positional deviation amount calculation step (S130) to the determination step (S134) are repeated until writing of all the stripe regions 32 for the second writing processing has been completed.

In the second correction amount map generation step (S136), the correction amount map generation unit 66 generates, with respect to the whole surface of the target object 101, the second correction amount map whose element value is a correction amount (dx2ndn, dy2ndn) for the second writing processing for each global mesh region 11 (xn, yn). The second correction amount map is stored in the storage device 142.

In the first writing step (S174), the shot data generation unit 70 calculates, for each pixel 36, an incident dose D(x) (amount of dose) with which the pixel 36 concerned is irradiated in the first writing processing. In other words, the incident dose D(x) (amount of dose) is calculated by multiplying the dose defined in the dose map by the base dose D_{base}. If the incident dose D(x) (amount of dose) is defined in the dose map, it may be used as it is.

Next, the shot data generation unit 70 calculates an irradiation time for each pixel 36 for the first writing processing. The irradiation time for each pixel 36 can be obtained by diving an incident dose D(x) of a pixel concerned by a current density J.

The data processing unit 72 rearranges obtained irradiation time data for each pixel 36 in the order of shot for the first writing processing, and stores it in the storage device 142. The transmission processing unit 74 transmits, in the order of shot, the irradiation time data to the deflection control circuit 130.

Under the control of the writing control unit 76, the writing mechanism 150 writes a pattern on the target object 101 with the multiple beams 20 (electron beam), based on the beam irradiation position corrected by the correction amount (dx1stn, dy1stn). In other words, the writing mechanism 150 performs the first correction in the first writing processing, based on a difference between the writing-time positional deviation amount in the first writing processing and the final positional deviation amount. The writing mechanism 150 performs writing while moving the XY stage 105. Specifically, under the control of the deflection control circuit 130 (an example of a correction unit), for each tracking cycle of the multiple beams 20, the deflector 208 deflects a beam array (irradiation region) to a position corrected by a correction amount (dx1stn, dy1stn) of the global mesh region 11 where a representative position (e.g., center position or center beam position) of the beam array is included. The deflection position of the beam array (irradiation region 34) is set based on the representative position (for example, a center position or center beam position) of the beam array described above.

In the second writing step (S176), the shot data generation unit 70 calculates, for each pixel 36, an incident dose D(x) (amount of dose) with which the pixel 36 concerned is irradiated in the second writing processing. In other words, the incident dose D(x) (amount of dose) is calculated by multiplying the dose defined in the dose map by the base dose D_{base}. If the incident dose D(x) (amount of dose) is defined in the dose map, it may be used as it is.

Next, the shot data generation unit 70 calculates an irradiation time for each pixel 36 for the second writing processing. The irradiation time for each pixel 36 can be obtained by diving an incident dose D(x) of a pixel concerned by a current density J.

The data processing unit 72 rearranges obtained irradiation time data for each pixel 36 in the order of shot for the second writing processing, and stores it in the storage device 142. The transmission processing unit 74 transmits, in the order of shot, the irradiation time data to the deflection control circuit 130.

Under the control of the writing control unit 76, the writing mechanism 150 writes a pattern on the target object 101 with the multiple beams 20 (electron beam), based on the beam irradiation position corrected by the correction amount (dx2ndn, dy2ndn). In other words, the writing mechanism 150 performs the second correction in the second writing processing, based on a difference between the writing-time positional deviation amount and the final positional deviation amount in the second writing processing. The writing mechanism 150 performs writing while moving the XY stage 105. Specifically, under the control of the deflection control circuit 130 (an example of a correction unit), for each tracking cycle of the multiple beams 20, the deflector 208 deflects a beam array (irradiation region) to a position corrected by a correction amount (dx2ndn, dy2ndn) of the global mesh region 11 where a representative position (e.g., center position or center beam position) of the beam array is included. The deflection position of the beam array (irradiation region 34) is set based on the representative position (for example, a center position or center beam position) of the beam array described above.

In a modified example of the second embodiment, similarly to the modified example of the first embodiment, the formation position of a pattern may be corrected in pattern data.

In the modified example of the second embodiment, in the first writing step (S174), the shot data generation unit 70, first, corrects a pattern formation position in the writing data, based on the first correction amount map whose element value is a correction amount (dx1stn, dy1stn) for the first writing processing for each global mesh region 11 (xn, yn). Specifically, it operates as follows: The shot data generation unit 70 corrects, for each global mesh region 11, the position of a pattern included in the global mesh region 11 concerned by a correction amount defined for the global mesh region 11 concerned.

Then, the shot data generation unit 70 newly generates a dose map for the first writing processing by using a corrected pattern layout. The contents of the method of generating a dose map is the same as those described above. The shot data generation unit 70 calculates an irradiation time for each pixel 36. The irradiation time for each pixel 36 can be calculated by dividing an incident dose D(x) of a pixel concerned by a current density J.

The data processing unit 72 rearranges obtained irradiation time data for each pixel 36 in the order of shot, and stores it in the storage device 142. The transmission processing unit 74 transmits the irradiation time data to the deflection control circuit 130 in the order of shot.

Under the control of the writing control unit 76, the writing mechanism 150 writes a pattern on the target object 101 with the multiple beams 20 (electron beam) as the first writing processing, based on the beam irradiation position corrected by the correction amount. In the modified example of the second embodiment, in both the real time mode and the preprocessing mode, the position of a pattern has already been corrected by the correction amount (dx1stn, dy1stn) in pattern data. Therefore, in performing writing, under the control of the deflection control circuit 130, the deflector 208 deflects, in each tracking cycle, a representative position (e.g., center position or center beam position) of the beam array to its design position, and during the tracking cycle, at that position, while each beam writes (exposes), for example, four pixels 36, the beam array (irradiation region 34) is made to follow the movement of the XY stage 105 by collectively deflecting all of the multiple beams 20 by the deflector 208 in order that the relative position between the beam array (irradiation region 34) and the target object 101 may not be displaced by the movement of the XY stage 105.

Similarly, in the second writing step (S176), the shot data generation unit 70, first, corrects a pattern formation position in the writing data, based on the second correction amount map whose element value is a correction amount (dx2ndn, dy2ndn) for the second writing processing of each global mesh region (xn, yn). Specifically, it operates as follows: The shot data generation unit 70 corrects, for each global mesh region 11, the position of a pattern included in the global mesh region 11 concerned by a correction amount defined for the global mesh region 11 concerned.

Then, the shot data generation unit 70 newly generates a dose map for the first writing processing by using a corrected pattern layout. The contents of the method of generating a dose map is the same as those described above. The shot data generation unit 70 calculates an irradiation time for each pixel 36. The irradiation time for each pixel 36 can be calculated by dividing an incident dose D(x) of the pixel concerned by a current density J.

The data processing unit 72 rearranges obtained irradiation time data for each pixel 36 in the order of shot, and stores it in the storage device 142. The transmission processing unit 74 transmits the irradiation time data to the deflection control circuit 130 in the order of shot.

Under the control of the writing control unit 76, the writing mechanism 150 writes a pattern on the target object 101 with the multiple beams 20 (electron beam) as the second writing processing, based on the beam irradiation position corrected by the correction amount. In the modified example of the second embodiment, in both the real time mode and the preprocessing mode, the position of a pattern has already been corrected by the correction amount (dx2ndn, dy2ndn) in pattern data. Therefore, in performing writing, under the control of the deflection control circuit 130, the deflector 208 deflects, in each tracking cycle, a representative position (e.g., center position or center beam position) of the beam array to its design position, and during the tracking cycle, at that position, while each beam writes (exposes), for example, four pixels 36, the beam array (irradiation region 34) is made to follow the movement of the XY stage 105 by collectively deflecting all of the multiple beams 20 by the deflector 208 in order that the relative position between the beam array (irradiation region 34) and the target object 101 may not be displaced by the movement of the XY stage 105.

As described above, according to the second embodiment, it is possible to correct a positional deviation of the beam irradiation position and pattern formation position in two-stroke writing deviated because of an irreversible deformation of the target object 101 due to irradiation of the multiple beams 20 (electron beam).

### Third Embodiment

A third embodiment describes the case where, relating to the two-stroke writing explained in the second embodiment, in the case of performing writing without correction in the first writing processing, the second writing processing is performed such that the writing position of the second writing processing is matched to the position written without correction in the first writing processing. The configuration of the writing apparatus 100 of the third embodiment is the same as that of FIG. 18 except that the final positional deviation amount calculation unit 52, the correction amount calculation unit 56, and the correction amount map generation unit 58 are omitted.

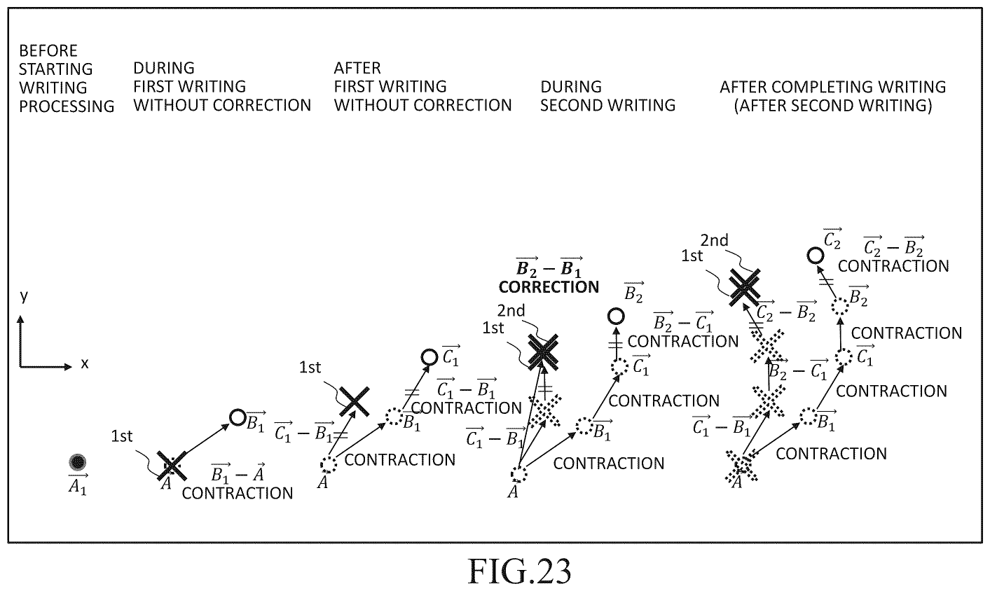

FIG. 23 is an illustration showing an example of a positional deviation state of a substrate surface according to the third embodiment. FIG. 23 shows a state before starting the first writing processing, a state during writing at a desired position in the first writing processing, a state after completing the first writing processing, a state during writing at a desired position in the second writing processing, and a state after completing the second writing process.

In FIG. 23, the vector A indicates a design beam irradiation position. While the first writing processing proceeds for the target LTEM substrate, if the position of the vector A before starting writing processing is written as it is without correcting, at the time of writing the position of the vector A in the second writing processing, the position of the vector A before starting writing processing has physically moved, by a vector of (vector B₂−vector B₁), from the position of the vector A before starting writing processing to the moved position (vector A+(vector B₂−vector B₁)) because a deformation due to contraction of the substrate occurred as shown in FIG. 23.

In the third embodiment, since the same layout pattern as that of the first writing processing is used in the second writing processing, writing of the second writing processing is performed to be superimposed (overlapped) on the beam irradiation position of the first writing processing. Therefore, at the time of writing in the second writing processing, the position corrected, by a vector of (vector B₂−vector B₁), from the position of the vector A before starting writing processing to a corrected position (vector A+(vector B₂−vector B₁)) is written as a beam irradiation position (or a pattern formation position). Thereby, at the time of completion of the writing processing for the whole substrate after the second writing processing, the beam irradiation position (or pattern formation position) written in the first writing processing and the beam irradiation position (or pattern formation position) written in the second writing processing can be the same position although being different from the position of the vector A before starting writing processing.

The flowchart showing an example of main steps of the writing method according to the third embodiment is the same as that of FIG. 22 except for that the final positional deviation amount (vector C₂) calculation step (S105), the correction amount calculation step (S122), the determination step (S124), and the first correction amount map generation step (S126) are omitted. According to the third embodiment, since correction is not performed in first writing processing, a correction amount is calculated in first writing processing.

In the third embodiment, the contents of the dose map generation step (S103), the writing schedule generation step (S107), and the writing-time positional deviation amount (vector B₁) calculation step (S120) are the same as those explained with reference to FIG. 22. In other words, in the writing-time positional deviation amount (vector B₁) calculation step (S120), when executing the first writing processing and the second writing processing performed after the first writing processing by using electron beams onto the target object 101 which deforms irreversibly due to irradiation with electron beams, the writing-time positional deviation amount calculation unit 54 calculates a positional deviation amount (another example of the first positional deviation amount) of a pattern formation position or a beam irradiation position deviated from its design position at the time of irradiation of an electron beam concerned because of an irreversible deformation of the target object 101 generated by electron beam irradiation onto the target object 101 having been performed before the irradiation of the electron beam concerned onto the pattern formation position or the beam irradiation position in the first writing processing. Specifically, the writing-time positional deviation amount calculation unit 54 calculates a positional deviation amount (vector B₁) at the time of writing a representative position in each global mesh region 11. The vector B₁ of each global mesh region 11 is calculated as a writing-time positional deviation amount (dx1stwrite-n, dy1stwrite-n). n indicates the index of each global mesh region 11. The writing-time positional deviation amount of the global mesh region 11 where a pattern formation position or a beam irradiation position is included corresponds to the writing-time positional deviation amount of the formation position of the pattern concerned or the beam irradiation position. The writing-time positional deviation amount (dx1stwrite-n, dy1stwrite-n) of each global mesh region 11 depends on a dose (irradiation coefficient) defined in the dose map, and, as described above, can be similarly calculated using a finite element method, for example.

In the example described above, a writing-time positional deviation amount is calculated for each global mesh region 11. However, it is not limited thereto. It is also preferable to calculate a writing-time positional deviation amount for each representative position (e.g., center position or position of center beam) of a beam array at the time of an actual shot.

The contents of the writing-time positional deviation amount (vector B₂) calculation step (S130) in the third embodiment are the same as those explained with reference to FIG. 22.

In the correction amount calculation step (S132), based on the positional deviation amount (vector B₁), the correction amount calculation unit 64 calculates a correction amount (vector B₂−vector B₁) (another example of the first correction amount) for correcting a pattern formation position or a beam irradiation position at the time of irradiation of an electron beam in the second writing processing which is corresponding to the electron beam concerned in the first writing processing. The correction amount (vector B₂−vector B₁) (another example of the first correction amount) is calculated as a difference between the writing-time positional deviation amount (vector B₂) in the second writing processing and the writing-time positional deviation amount (vector B₁) in the first writing processing. In other words, the correction amount (dx2ndn, dy2ndn) of each position in the n-th beam-irradiated (written) global mesh region 11 can be calculated by a subtraction of “the writing-time positional deviation amount (dx2ndwrite-n, dy2ndwrite-n)”−“the writing-time positional deviation amount (dx1stwrite-n, dy1stwrite-n)”.

The contents of the determination step (S134) and the second correction amount map generation step (S136) in the third embodiment are the same as those explained with reference to FIG. 22.

In the first writing step (S174), the shot data generation unit 70 calculates an irradiation time for each pixel 36 by using the dose map for the first writing processing. The irradiation time for each pixel 36 can be calculated by dividing an incident dose D(x) of a pixel concerned by a current density J.

The data processing unit 72 rearranges obtained irradiation time data for each pixel 36 in the order of shot, and stores it in the storage device 142. The transmission processing unit 74 transmits the irradiation time data to the deflection control circuit 130 in the order of shot.

Under the control of the writing control unit 76, the writing mechanism 150 writes a pattern on the target object 101 with the multiple beams 20 (electron beam) as the first writing processing. In the third embodiment, in both the real time mode and the preprocessing mode, in performing writing, under the control of the deflection control circuit 130, the deflector 208 deflects, in each tracking cycle, a representative position (e.g., center position or center beam position) of the beam array to its design position, and during the tracking cycle, at that position, while each beam writes (exposes), for example, four pixels 36, the beam array (irradiation region 34) is made to follow the movement of the XY stage 105 by collectively deflecting all of the multiple beams 20 by the deflector 208 in order that the relative position between the beam array (irradiation region 34) and the target object 101 may not be displaced by the movement of the XY stage 105.

In the second writing step (S176), the shot data generation unit 70 calculates, for each pixel 36, an incident dose D(x) (amount of dose) with which the pixel 36 concerned is irradiated in the second writing processing. In other words, the incident dose D(x) (amount of dose) is calculated by multiplying the dose defined in the dose map by the base dose D_{base}. If the incident dose D(x) (amount of dose) is defined in the dose map, it may be used as it is.

Next, the shot data generation unit 70 calculates an irradiation time for each pixel 36 for the second writing processing. The irradiation time for each pixel 36 can be obtained by diving an incident dose D(x) of a pixel concerned by a current density J.

The data processing unit 72 rearranges obtained irradiation time data for each pixel 36 in the order of shot for the second writing processing, and stores it in the storage device 142. The transmission processing unit 74 transmits, in the order of shot, the irradiation time data to the deflection control circuit 130.

Under the control of the writing control unit 76, the writing mechanism 150 writes a pattern on the target object 101 with the multiple beams 20 (electron beam), based on the beam irradiation position corrected by the correction amount (dx2ndn, dy2ndn). The writing mechanism 150 performs writing while moving the XY stage 105. Specifically, under the control of the deflection control circuit 130 (an example of a correction unit), for each tracking cycle of the multiple beams 20, the deflector 208 deflects a beam array (irradiation region) to the position corrected by a correction amount (dx2ndn, dy2ndn) of the global mesh region 11 where a representative position (e.g., center position or center beam position) of the beam array is included. The deflection position of the beam array (irradiation region 34) is set based on the representative position (for example, a center position or center beam position) of the beam array described above.

In a modified example of the third embodiment, similarly to the modified example of the second embodiment, the formation position of a pattern may be corrected in pattern data.

The contents of the first writing step (S174) in the modified example of the third embodiment are the same as those of the first writing step (S174) of the third embodiment.

In the second writing step (S176) in the modified example of the third embodiment, the shot data generation unit 70, first, corrects a pattern formation position in the writing data, based on the correction amount map whose element value is a correction amount (dx2ndn, dy2ndn) for the second writing processing for each global mesh region (xn, yn). Specifically, it operates as follows: The shot data generation unit 70 corrects, for each global mesh region 11, the position of a pattern included in the global mesh region 11 concerned by a correction amount defined for the global mesh region 11 concerned.

Then, the shot data generation unit 70 newly generates a dose map for the first writing processing by using a corrected pattern layout. The contents of the method of generating a dose map is the same as those described above. The shot data generation unit 70 calculates an irradiation time for each pixel 36. The irradiation time for each pixel 36 can be calculated by dividing an incident dose D(x) of a pixel concerned by a current density J.

The data processing unit 72 rearranges obtained irradiation time data for each pixel 36 in the order of shot, and stores it in the storage device 142. The transmission processing unit 74 transmits the irradiation time data to the deflection control circuit 130 in the order of shot.

Under the control of the writing control unit 76, the writing mechanism 150 writes a pattern on the target object 101 with the multiple beams 20 (electron beam) as the second writing processing, based on the beam irradiation position corrected by the correction amount. In the modified example of the third embodiment, in both the real time mode and the preprocessing mode, the position of a pattern has already been corrected by the correction amount (dx2ndn, dy2ndn) in pattern data. Therefore, in performing writing, under the control of the deflection control circuit 130, the deflector 208 deflects, in each tracking cycle, a representative position (e.g., center position or center beam position) of the beam array to its design position, and during the tracking cycle, at that position, while each beam writes (exposes), for example, four pixels 36, the beam array (irradiation region 34) is made to follow the movement of the XY stage 105 by collectively deflecting all of the multiple beams 20 by the deflector 208 in order that the relative position between the beam array (irradiation region 34) and the target object 101 may not be displaced by the movement of the XY stage 105.

As described above, according to the third embodiment, even when correcting a positional deviation of a beam irradiation position or a pattern formation position of the first stroke of the two-stroke writing is not performed, a positional deviation of a beam irradiation position or a pattern formation position due to an irreversible deformation of the target object 101 resulting from irradiation of the multiple beams 20 (electron beam) can be corrected in the second stroke.

### Fourth Embodiment

A fourth embodiment describes the case where, after completing the first writing processing for the whole writing region (chip region) of the target object 101, the target object 101 is carried out to be developed, etched, and applied with resist, and then, again placed on the stage 105 in order that superimposed writing being the second writing processing may be performed for the whole writing region (chip region) of the target object 101 by using a different layout pattern.

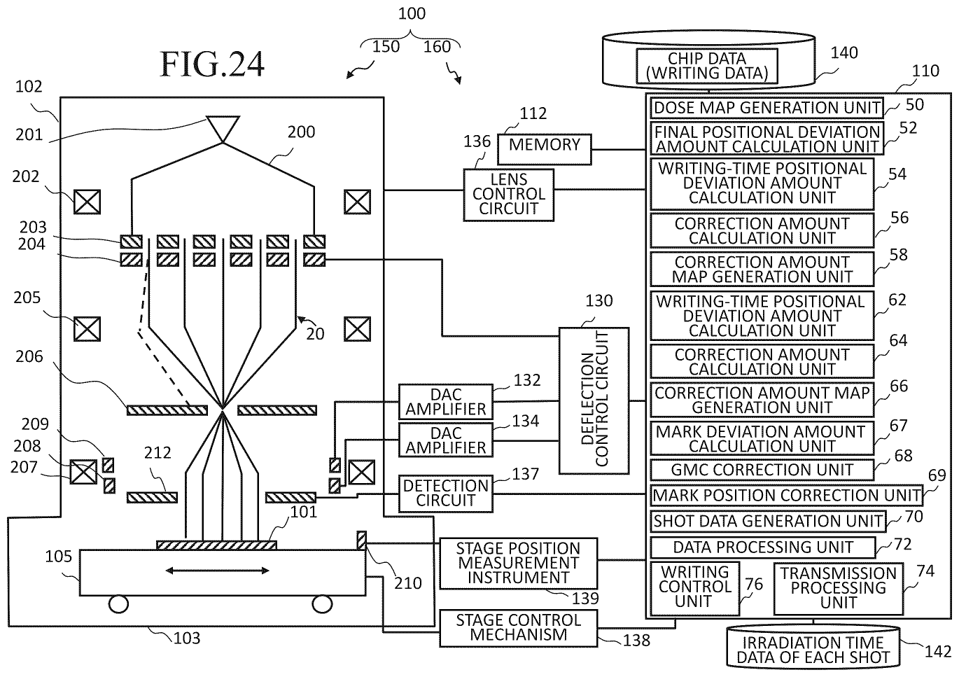

FIG. 24 is a conceptual diagram showing a configuration of a writing apparatus according to the fourth embodiment. FIG. 24 is the same as FIG. 18 except that, further, a mark deviation amount calculation unit 67, a GMC (grid matching correction) correction unit 68, and a mark position correction unit 69 are added in the control computer 110, and a detection circuit 137 is additionally arranged, and further, a detector 212 is disposed in the electron optical column 102.

Each of the “ . . . units” such as the dose map generation unit 50, the final positional deviation amount calculation unit 52, the writing-time positional deviation amount calculation unit 54, the correction amount calculation unit 56, the correction amount map generation unit 58, the writing-time positional deviation amount calculation unit 62, the correction amount calculation unit 64, the correction amount map generation unit 66, the mark deviation amount calculation unit 67, the GMC correction unit 68, the mark position correction unit 69, the shot data generation unit 70, the data processing unit 72, the transmission processing unit 74, and the writing control unit 76 includes processing circuitry. The processing circuitry includes, for example, an electric circuit, a computer, a processor, a circuit board, a quantum circuit, a semiconductor device, or the like. Each “ . . . unit” may use common processing circuitry (the same processing circuitry), or different processing circuitry (separate processing circuitry). Information input/output to/from the dose map generation unit 50, the final positional deviation amount calculation unit 52, the writing-time positional deviation amount calculation unit 54, the correction amount calculation unit 56, the correction amount map generation unit 58, the writing-time positional deviation amount calculation unit 62, the correction amount calculation unit 64, the correction amount map generation unit 66, the mark deviation amount calculation unit 67, the GMC correction unit 68, the mark position correction unit 69, the shot data generation unit 70, the data processing unit 72, the transmission processing unit 74, and the writing control unit 76, and information being operated are stored in the memory 112 each time. Similarly to the second embodiment, one of the writing-time positional deviation amount calculation unit 54 and the writing-time positional deviation amount calculation units 62 may have both the functions of them. In that case, the other one may be omitted.

In the first writing processing, similarly to FIG. 19, writing is performed in the y direction in order from the stripe region 32 at the lower side to the upper side of the target object 101. After completing the first writing processing for the whole writing region (chip region) of the target object 101, the target object 101 is carried out to be developed, etched, and applied with resist, and then, again placed on the stage 105. As shown in the right side of FIG. 19, the second writing processing of superimposed writing on an already-written pattern layout is performed by using writing data of a different pattern layout. The right illustration of FIG. 19 shows a state of writing a certain position (denoted by x, which is corresponding to the left side position denoted by x) in the middle of the second writing processing.

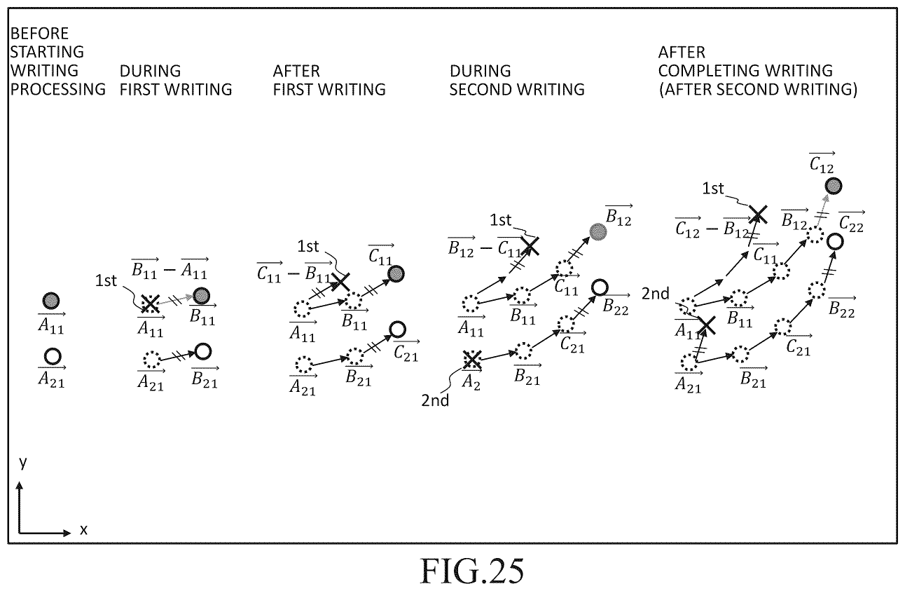

FIG. 25 is an illustration showing an example of a positional deviation state of a substrate surface according to a comparative example of the fourth embodiment. FIG. 25 shows a state before starting the first writing processing, a state during writing at a desired position in the first writing processing, a state after completing the first writing processing, a state during writing at a desired position in the second writing processing, and a state after completing the second writing process.

In FIG. 25, the vector A₁₁ indicates a design beam irradiation position in the first writing processing. The vector A₂₁ indicates a design beam irradiation position in the second writing processing. While the first writing processing proceeds for the target LTEM substrate, at the time of writing the position of the vector A₁₁ in the first writing processing, the position of the vector A₁₁ before starting writing processing has physically moved to the position of the vector B₁₁ because a deformation due to contraction of the substrate occurred as shown in FIG. 25. Similarly, the position of the vector A₂₁ before starting writing processing has physically moved to the position of the vector B₂₁ because a deformation due to contraction of the substrate occurred as shown in FIG. 25.

Then, along with the writing processing further proceeds, at the time of completion of the first writing processing, the position of the vector A₁₁ before starting writing processing has physically moved to the position of the vector C₁₁ because of a further deformation as shown in FIG. 25. Similarly, the position of the vector A₂₁ before starting writing processing has physically moved to the position of the vector C₂₁.

Then, starting the second writing processing, along with the writing processing proceeds, at the time of writing the position of the vector A₂₁ in the second writing processing, the position of the vector A₁₁ before starting writing processing has physically moved to the position of the vector B₁₂ because of a deformation due to contraction of the substrate as shown in FIG. 25. Similarly, the position of the vector A₂₁ before starting writing processing has physically moved to the position of the vector B₂₂.

Along with the writing processing further proceeds, at the time of completion of the second writing processing (after completing writing processing for the whole substrate), the position of the vector A₁₁ before starting writing processing has physically moved to the position of the vector C₁₂ because of a further deformation as shown in FIG. 25. Similarly, the position of the vector A₂₁ before starting writing processing has physically moved to the position of the vector C₂₂.

Therefore, if the position of the vector A₁₁ before staring writing processing is written as it is in the first writing processing, at the time of completion of the writing processing for the whole substrate, the written beam irradiation position has deviated, by a vector of (vector C₁₂−vector B₁₁), from the position of the vector A₁₁ before starting writing processing to the moved position (vector A+(vector C₁₂−vector B₁₁)). Similarly, if the position of the vector A₂₁ before starting writing processing is written as it is in the second writing processing, at the time of completion of the writing processing for the whole substrate, the written beam irradiation position has deviated, by a vector of (vector C₁₂−vector B₁₂), from the position of the vector A₂₁ before starting writing processing to the moved position (vector A₂₁+(vector C₁₂−vector B₁₂)). Then, according to the fourth embodiment, the writing-time irradiation position (pattern formation position) is corrected in order to let the beam irradiation position of the first writing processing be the position of the vector A₁₁ before starting writing processing, and to let the beam irradiation position of the second writing processing be the position of the vector A₂₁ before starting writing processing when the writing processing has completed, even in the case of an irreversible deformation occurring in the substrate.

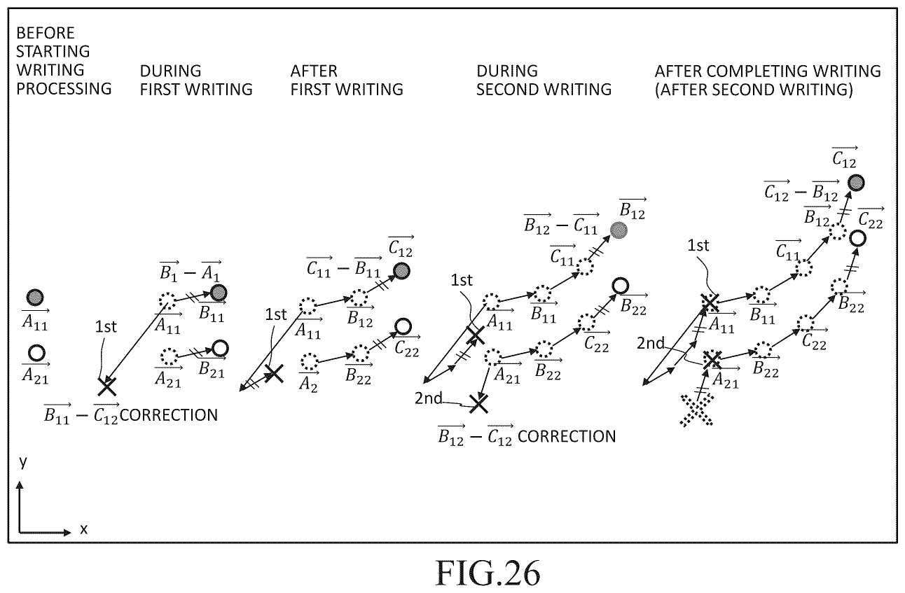

FIG. 26 is an illustration showing an example of a positional deviation state of a substrate surface according to the fourth embodiment. The state of deformation of the substrate surface of the fourth embodiment is not illustrated. In FIG. 26, the vector A₁₁ indicates a design beam irradiation position in the first writing processing. The vector A₂₁ indicates a design beam irradiation position in the second writing processing.

While the first writing processing proceeds for the target LTEM substrate, at the time of writing the position of the vector A₁₁ in the first writing processing, the position of the vector A₁₁ before starting writing processing has physically moved to the position of the vector B₁₁ because a deformation due to contraction of the substrate occurred as shown in FIG. 26. Similarly, the position of the vector A₂₁ before starting writing processing has physically moved to the position of the vector B₂₁ because a deformation due to contraction of the substrate occurred as shown in FIG. 26.

Then, after completing the first writing processing, and further after completing the second writing processing, that is at the time of completion of writing the whole substrate, the position of the vector A₁₁ before starting writing processing has physically moved to the position of the vector C₁₂ because of a further deformation as shown in FIG. 26. Similarly, the position of the vector A₂₁ before starting writing processing has physically moved to the position of the vector C₂₂.

Therefore, when writing in the first writing processing, it is sufficient to perform correction to be corrected by the positional deviation amount (vector C₁₂−vector B₁₁) which is from the position (vector B₁₁) at that time to the position (vector C₁₂) after completion of the writing processing for the whole substrate. Therefore, at the time of writing in the first writing processing, the position corrected, by a vector of (vector B₁₁−vector C₁₂), from the position of the vector A₁₁ before starting writing processing to a corrected position (vector A₁₁+(vector B₁₁−vector C₁₂)) is written as a beam irradiation position (or pattern formation position). Thereby, after the second writing processing, that is after completing writing processing for the whole substrate, the beam irradiation position (or pattern formation position) written in the first writing processing can be the position of the vector A₁₁ being the position moved from the position (vector A₁₁+(vector B₁₁−vector C₁₂)) by a vector of (vector C₁₂−vector B₁₁).

At the time of writing the position of the vector A₂₁ in the second writing processing, the position of the vector A₂₁ before starting writing processing has physically moved to the position of the vector B₂₂ because a deformation due to contraction of the substrate occurred as shown in FIG. 26. This positional moved deviation amount is the same as the positional deviation amount (vector B₁₂−vector A₁₁) in the case where the position of the vector A₁₁ before starting processing has moved to the position of the vector B₁₂. After completion of the second writing processing, that is after completion of the writing processing for the whole substrate, the position of the vector A₂₁ before starting writing processing has physically moved to the position of the vector C₂₂ as described above. This positional moved deviation amount is the same as the positional deviation amount (vector C₁₂−vector A₁₁) in the case where the position of the vector A₁₁ before starting processing has moved to the position of the vector C₁₂.

Therefore, when writing in the second writing processing, it is sufficient to perform correction to be corrected by the positional deviation amount (vector C₂₂−vector B₂₂) which is from the position (vector B₂₂) at that time to the position (vector C₂₂) after completing writing processing for the whole substrate. This positional moved deviation amount is the same as the positional deviation amount (vector C₂₂−vector B₁₂) in the case where the position (vector B₁₂) has moved to the position (vector C₁₂) after completing writing processing for the whole substrate. Therefore, at the time of writing in the second writing processing, the position corrected, by a vector of (vector B₁₂−vector C₁₂), from the position of the vector A₂₁ before starting writing processing to a corrected position (vector A₂₁+(vector B₁₂−vector C₁₂)) is written as a beam irradiation position (or pattern formation position). Thereby, after the second writing processing, that is after completing writing processing for the whole substrate, the beam irradiation position (or pattern formation position) written in the second writing processing can be the position of the vector A₂₁ being the position moved from the position (vector A₂₁+(vector B₁₂−vector C₁₂)) by a vector of (vector C₁₂−vector B₁₂).

Accordingly, when completing writing processing for the whole substrate, both of the beam irradiation position written in the first writing processing and the beam irradiation position written in the second writing processing can be the positions of the vectors A₁₁ and A₂₁ before starting writing processing. Therefore, the relative position relationship between both the positions can be maintained.

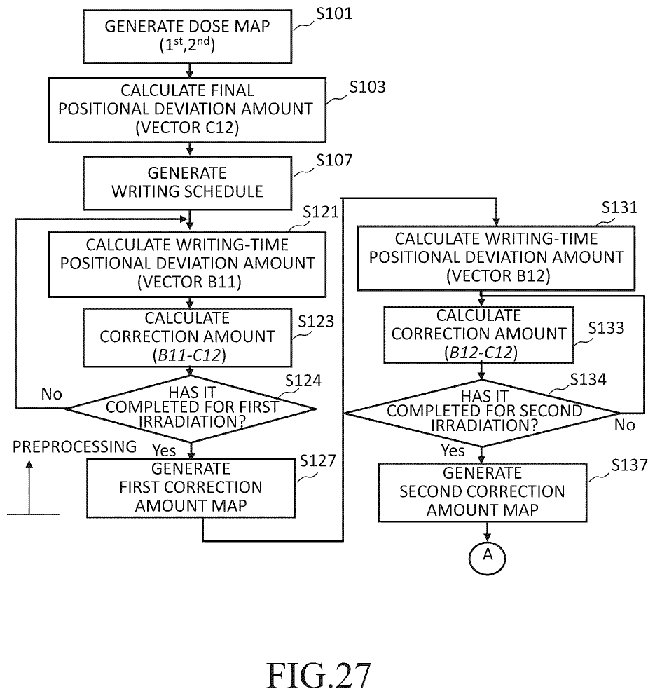

FIG. 27 is a flowchart showing some portions of an example of main steps of a writing method according to the fourth embodiment.

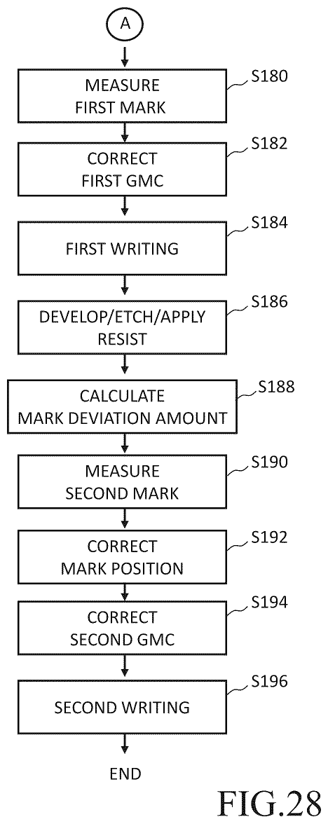

FIG. 28 is a flowchart showing other portions of the example of the main steps of the writing method according to the fourth embodiment.

In FIGS. 27 and 28, the writing method of the fourth embodiment executes a series of steps: the dose map generation step (S101), a final positional deviation amount (vector C₂) calculation step (S103), the writing schedule generation step (S107), a writing-time positional deviation amount (vector B₁₁) calculation step (S121), a correction amount calculation step (S123), the determination step (S124), a first correction amount map generation step (S127), a writing-time positional deviation amount (vector B₁₂) calculation step (S131), a correction amount calculation step (S133), the determination step (S134), a second correction amount map generation step (S137), a first mark measurement step (S180), a first GMC correction step (S182), a first writing step (S184), a development/etching/resist-application step (S186), a mark deviation amount calculation step (S188), a second mark measurement step (S190), a mark position correction step (S192), a second GMC correction step (S194), and a second writing step (S196). The writing processing according to the fourth embodiment includes the first writing processing for writing the first chip pattern, and the second writing processing, performed after the first writing processing, for writing the second chip pattern to be superimposed (overlapped) on the first chip pattern. The second chip pattern of the fourth embodiment is different from the first chip pattern.

FIGS. 27 and 28 show flowcharts in the case where writing processing is performed in a pre-processing mode of starting a writing operation after performing a calculation process, as a pre-process, for correcting beam irradiation positions (or pattern formation positions) in all the regions. It is omitted to show a flowchart of performing writing processing in a real-time mode of executing a calculation process for correcting a beam irradiation position (or pattern formation position) in the next region while performing a writing operation.

In a real-time mode, after performing the first mark measurement step (S180) and the first GMC correction step (S182), a writing operation for the k-th stripe region in the first writing processing, and a correction calculation process for the (k+m)th stripe region (that is, the writing-time positional deviation amount (vector B₁₁) calculation step (S121)), the correction amount calculation step (S123), the determination step (S124), and the first correction amount map generation step (S127)) are carried out at the same period. Then, with respect to the stripe region 32 for which the correction calculation processing has been completed, the first writing step (S194) is performed sequentially. Next, after performing the development/etching/resist-application step (S186), the mark deviation amount calculation step (S188), the second mark measurement step (S190), the mark position correction step (S192), and the second GMC correction step (S194), a writing operation for the k-th stripe region in the second writing processing, and a correction calculation process for the (k+m)th stripe region (that is, the writing-time positional deviation amount (vector B₁₂) calculation step (S131)), the correction amount calculation step (S133), the determination step (S134), and the second correction amount map generation step (S136)) are carried out at the same period. Then, with respect to the stripe region 32 for which the correction calculation processing has been completed, the second writing step (S196) is performed sequentially.

In the dose map generation step (S101), the dose map generation unit 50 generates a dose map in which a dose is defined for each pixel. Here, the dose map generation unit 50 generates a dose map (the first dose map) for the first writing processing and a dose map (the second dose map) for the second writing processing. The method of generating a dose map may be the same as that of the dose map generation step (S102) described above.

In the final positional deviation amount (vector C₁₂) calculation step (S103), in the case of writing a pattern with electron beams on the target object 101 which irreversibly deforms due to electron beam irradiation, the final positional deviation amount calculation unit 52 calculates a final positional deviation amount (the first positional deviation amount) of a pattern formation position or beam irradiation position deviated from its design position because of an irreversible deformation of the target object 101 after completion of the writing processing. Specifically, the final positional deviation amount calculation unit 52 calculates a positional deviation amount (vector C₁₂) of each position after the first and second writing processing has completed, and, that is, after completion of the writing processing to the target object 101.

The final positional deviation amount calculation unit 52 calculates the vector C₁₂ at a representative point (e.g., center position) in each global mesh region 11 (position). Each vector C₁₂ is calculated as a final positional deviation amount (dxfinal-i, dyfinal-i). i indicates the index of each global mesh region 11. The final positional deviation amount of the global mesh region 11 where a pattern formation position or a beam irradiation position is included corresponds to the final positional deviation amount of the formation position of the pattern concerned or the beam irradiation position. The final positional deviation amount (dxfinal-i, dyfinal-i) of each global mesh region 11 is depending on a dose (irradiation coefficient) defined in the dose map, and can be calculated using a finite element method as described above.

In the writing schedule generation step (S107), the writing control unit 76 generates a writing schedule which defines the order of shot of each pixel defined in the dose map. Here, a writing schedule is generated for each of the first writing processing and the second writing processing. Thereby, for each shot, positions and dose amounts having been irradiated by the time (writing time) of performing a shot concerned can be known.

In the writing-time positional deviation amount (vector B₁₁) calculation step (S121), in the first writing processing, the writing-time positional deviation amount calculation unit 54 calculates a writing-time positional deviation amount (the second positional deviation amount) deviated from a design position because of an irreversible deformation of the target object 101 generated by electron beam irradiation onto the target object 101 having been performed before irradiation of the current electron beam concerned. In other words, the writing-time positional deviation amount calculation unit 54 calculates a writing-time positional deviation amount (the second positional deviation amount) of a pattern formation position or a beam irradiation position deviated from its design position at the time of irradiation of an electron beam concerned because of an irreversible deformation of the target object 101 generated by electron beam irradiation onto the target object 101 having been performed before irradiation of the electron beam concerned in the first writing processing. Specifically, the writing-time positional deviation amount calculation unit 54 calculates a positional deviation amount (vector B₁₁) at the time of writing a representative position in each global mesh region 11. The vector B₁₁ of each global mesh region 11 is calculated as a writing-time positional deviation amount (dx1stwrite-n, dy1stwrite-n). n indicates the index of each global mesh region 11. The writing-time positional deviation amount of the global mesh region 11 where a pattern formation position or a beam irradiation position is included corresponds to the writing-time positional deviation amount of the formation position of the pattern concerned or the beam irradiation position. The writing-time positional deviation amount (dx1stwrite-n, dy1stwrite-n) of each global mesh region 11 depends on a dose (irradiation coefficient) defined in the dose map, and, as described above, can be similarly calculated using a finite element method, for example.

In the example described above, a writing-time positional deviation amount is calculated for each global mesh region 11. However, it is not limited thereto. It is also preferable to calculate a writing-time positional deviation amount for each representative position (e.g., center position or position of center beam) of a beam array at the time of an actual shot.

In the correction amount calculation step (S123), based on a final positional deviation amount due to an irreversible deformation of the target object 101 after completion of writing, the correction amount calculation unit 56 calculates a correction amount (vector B₁₁−vector C₁₂) (the first correction amount) for correcting a pattern formation position or a beam irradiation position in the case of applying an electron beam (the multiple beams 20) concerned to the target object 101. The correction amount (vector B₁₁−vector C₁₂) (the first correction amount) is calculated as a difference between the writing-time positional deviation amount (vector B₁₁) in the first writing processing and the final positional deviation amount (vector C₁₂). In other words, based on a difference between the writing-time positional deviation amount in the first writing processing and the final positional deviation amount, the correction amount calculation unit 56 calculates the first correction amount in the first writing processing. Further, in other words, the correction amount (dx1stn, dy1stn) of each position in the n-th beam-irradiated (written) global mesh region 11 can be calculated by a subtraction of “the writing-time positional deviation amount (dx1stwrite-n, dy1stwrite-n)”−“the final positional deviation amount (dxfinal-n, dyfinal-n)”.

In the determination step (S124), the writing control unit 76 determines whether calculation of the correction amount with respect to all the stripe regions 32 for the first writing processing has been completed. When not completed, it returns to the writing-time positional deviation amount calculation step (S121), and, with respect to the next stripe region 32, steps from the writing-time positional deviation amount calculation step (S121) to the determination step (S124) are repeated. Thus, steps from the writing-time positional deviation amount calculation step (S121) to the determination step (S124) are repeated until writing of all the stripe regions 32 has been completed.

In the first correction amount map generation step (S127), the correction amount map generation unit 58 generates, with respect to the whole surface of the target object 101, the first correction amount map whose element value is a correction amount (dx1stn, dy1stn) for the first writing processing for each global mesh region (xn, yn). The first correction amount map is stored in the storage device 142.

In the writing-time positional deviation amount (vector B₁₂) calculation step (S131), in the second writing processing, the writing-time positional deviation amount calculation unit 62 calculates a writing-time positional deviation amount (the third positional deviation amount) deviated from a design position because of an irreversible deformation of the target object 101 generated by electron beam irradiation onto the target object 101 having been performed before irradiation of the current electron beam concerned. In other words, the writing-time positional deviation amount calculation unit 62 calculates a writing-time positional deviation amount (the third positional deviation amount) of a pattern formation position or a beam irradiation position deviated from its design position at the time of irradiation of an electron beam in the second writing processing corresponding to the electron beam concerned in the first writing processing, deviated because of an irreversible deformation of the target object 101 generated by electron beam irradiation onto the target object 101 having been performed before irradiation of the electron beam concerned in the second writing processing corresponding to the electron beam concerned in the first writing processing. Specifically, the writing-time positional deviation amount calculation unit 62 calculates a positional deviation amount (vector B₁₂) at the time of writing a representative position in each global mesh region 11. The vector B₁₂ of each global mesh region 11 is calculated as a writing-time positional deviation amount (dx2ndwrite-n, dy2ndwrite-n). n indicates the index of each global mesh region 11. The writing-time positional deviation amount of the global mesh region 11 where a pattern formation position or a beam irradiation position is included corresponds to the writing-time positional deviation amount of the formation position of the pattern concerned or the beam irradiation position. The writing-time positional deviation amount (dx2ndwrite-n, dy2ndwrite-n) of each global mesh region 11 depends on a dose (irradiation coefficient) defined in the dose map, and, as described above, can be similarly calculated using a finite element method, for example.

As described above, it is also preferable to calculate a writing-time positional deviation amount for each representative position (e.g., center position or position of center beam) of a beam array at the time of an actual shot.

In the correction amount calculation step (S133), based on a final positional deviation amount due to an irreversible deformation of the target object 101 after completion of writing, the correction amount calculation unit 64 calculates a correction amount (vector B₁₂−vector C₁₂) (the second correction amount) for correcting a pattern formation position or a beam irradiation position in the case of applying an electron beam (the multiple beams 20) to the target object 101 in the second writing processing corresponding to the electron beam concerned in the first writing processing. The correction amount (vector B₁₂−vector C₁₂) (the second correction amount) is calculated as a difference between the writing-time positional deviation amount (vector B₂) in the second writing processing and the final positional deviation amount (vector C₂). In other words, based on a difference between the writing-time positional deviation amount in the second writing processing and the final positional deviation amount, the correction amount calculation unit 64 calculates the second correction amount in the second writing processing. Further, in other words, the correction amount (dx2ndn, dy2ndn) of each position in the n-th beam-irradiated (written) global mesh region 11 can be calculated by a subtraction of “the writing-time positional deviation amount (dx2ndwrite-n, dy2ndwrite-n)”−“the final positional deviation amount (dxfinal-n, dyfinal-n)”.

In the determination step (S134), the writing control unit 76 determines whether calculation of the correction amount with respect to all the stripe regions 32 for the second writing processing has been completed. When not completed, it returns to the writing-time positional deviation amount calculation step (S131), and, with respect to the next stripe region 32, steps from the writing-time positional deviation amount calculation step (S131) to the determination step (S134) are repeated. Thus, steps from the writing-time positional deviation amount calculation step (S131) to the determination step (S134) are repeated until writing of all the stripe regions 32 for the second writing processing has been completed.

In the second correction amount map generation step (S137), the correction amount map generation unit 66 generates, with respect to the whole surface of the target object 101, the second correction amount map whose element value is a correction amount (dx2ndn, dy2ndn) for the second writing processing for each global mesh region (xn, yn). The second correction amount map is stored in the storage device 142.

In the first mark measurement step (S180), before the first writing processing, the mark position (the first mark position) of the alignment mark 14 is measured. Specifically, the target object 101 is carried in the writing apparatus 100, and, in the state of it being placed on the stage 105, the mark positions of the alignment marks 14 formed at the four corners, for example, of the target object 101 are measured.

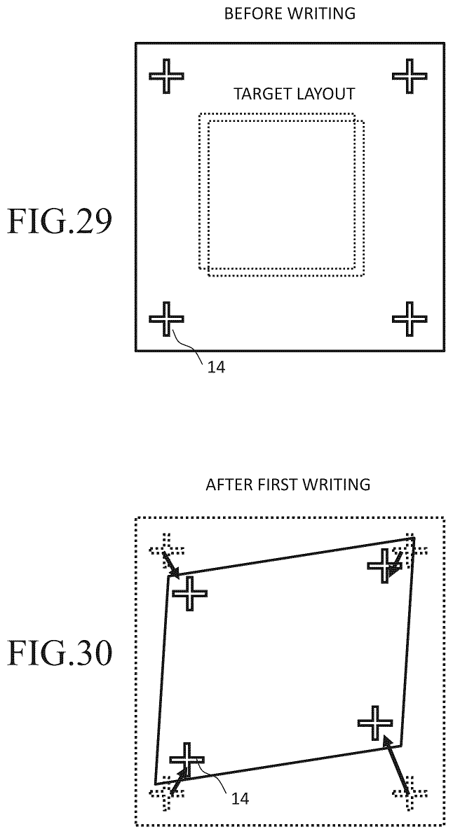

FIG. 29 is an illustration showing an example of a target object surface on which an alignment mark is formed according to the fourth embodiment. In FIG. 29, the alignment mark 14 for aligning is formed in advance on the target object 101. For example, a plurality of alignment marks 14 are formed. As each alignment mark 14, preferably, a cross pattern is formed, for example, as shown in FIG. 29. In the case of FIG. 29, there is a chip region, in which a pattern is to be formed, in the center section on the surface of the target object 101. The alignment marks 14 are formed, for example, at the four corners on the surface of the target object 101. Under the control of the writing control unit 76, the writing mechanism 150 scans an electron beam over each alignment mark 14, and detects, by the detector 212, a secondary electron emitted from the target object 101 surface including the alignment mark 14. Intensity data detected by the detector 212 is output to the detection circuit 137. After converting analog data to digital data, the detection circuit 137 amplifies the data to be output to the control computer 110.

In the first GMC correction step (S182), the GMC correction unit 68 performs grid matching correction of the pattern data, on the basis of the position of each measured alignment mark 14. For example, regarding the lower left mark position on the target object 101 as the original point, the x axis connecting the original point and the lower right mark position and the y axis connecting the original point and the upper left mark position are set. The position of the chip pattern (the first chip pattern) written on the target object 101 in the first writing processing is defined based on a measured mark position (the first mark position). Therefore, the GMC correction unit 68 corrects pattern data such that the coordinate system of the pattern data defined in writing data is in accordance with the x and y axes. Thereby, based on the original points obtained from a plurality of alignment marks 14, processes of parallel translation, rotation, and reduction/enlargement may be performed for each pattern data. The method of data conversion is not described here since it may be the same as the conventional one.

In the superimposed writing, the relative position relationship between the pattern written in the first writing processing and the pattern written in the second writing processing is important. A time period between the first writing processing and the second writing processing, the target object 101 is carried out from the stage 105. Therefore, the target object 101 is not necessarily arranged on the completely same position on the stage 105 in the first writing processing and in the second writing processing. Then, on the basis of the mark position, the pattern formation position in first writing processing and the pattern formation position in second writing processing are made to be matched with each other.

It is preferable to perform a mark measurement and a GMC correction also in each embodiment described above. Thereby, a pattern can be written based on the mark position on the surface of the target object 101.

In the first writing step (S184), the shot data generation unit 70 calculates, for each pixel 36, an incident dose D(x) (amount of dose) with which the pixel 36 concerned is irradiated in the first writing processing. In other words, the incident dose D(x) (amount of dose) is calculated by multiplying the dose defined in the dose map by the base dose D_{base}. If the incident dose D(x) (amount of dose) is defined in the dose map, it may be used as it is.

Next, the shot data generation unit 70 calculates an irradiation time for each pixel 36 for the first writing processing. The irradiation time for each pixel 36 can be obtained by diving an incident dose D(x) of a pixel concerned by a current density J.

The data processing unit 72 rearranges obtained irradiation time data for each pixel 36 in the order of shot for the first writing processing, and stores it in the storage device 142. The transmission processing unit 74 transmits, in the order of shot, the irradiation time data to the deflection control circuit 130.

Under the control of the writing control unit 76, the writing mechanism 150 writes a pattern on the target object 101 with the multiple beams 20 (electron beam), based on the beam irradiation position corrected by the correction amount (dx1stn, dy1stn). In other words, the writing mechanism 150 performs the second correction in the first writing processing, based on a difference between the writing-time positional deviation amount in the first writing processing and the final positional deviation amount. The writing mechanism 150 performs writing while moving the XY stage 105. Specifically, under the control of the deflection control circuit 130 (an example of a correction unit), for each tracking cycle of the multiple beams 20, the deflector 208 deflects a beam array (irradiation region) to a position corrected by a correction amount (dx1stn, dy1stn) of the global mesh region 11 where a representative position (e.g., center position or center beam position) of the beam array is included. The deflection position of the beam array (irradiation region 34) is set based on the representative position (e.g., a center position or center beam position) of the beam array described above.

In the development/etching/resist-application step (S186), the target object 101 is carried out from the writing apparatus 100 to be developed, etched, and applied with resist. Thereby, the pattern written in the first writing processing is formed on the surface of the target object 101. As for the target object 101, for example, a light shielding film, such as a chromium (Cr) film, is formed on the glass substrate, and a resist film is coated on the light shielding film. In the first writing processing, a chip pattern (the first chip pattern) of the first writing processing is written on the resist film. Then, a resist pattern along the chip pattern is formed by developing, and the chip pattern is formed on the light shielding film by etching and subsequent ashing. Next, in order to perform the second writing processing, the target object 101 is newly coated with a resist film, carried in the writing apparatus 100, and placed on the stage 105.

FIG. 30 is an illustration showing an example of a mark position after the first writing processing according to the fourth embodiment.

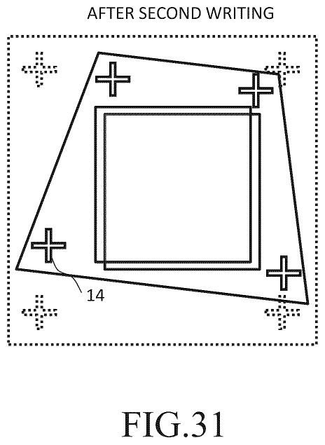

FIG. 31 is an illustration showing an example of a mark position after the second writing processing according to the fourth embodiment. Due to the first writing processing, the target object 101 deforms irreversibly as shown in FIG. 30. Due to the second writing processing, the target object 101 further deforms irreversibly as shown in FIG. 31. Therefore, the physical position of each alignment mark 14 on the target object 101 deviates because of the first writing processing and the second writing processing.

In the mark deviation amount calculation step (S188), the mark deviation amount calculation unit 67 calculates a positional deviation amount of the mark position, from the mark position (the first mark position) before starting the first writing processing, due to an irreversible deformation of the target object 101 after completing the first writing processing. Specifically, at the timing after completing the first writing processing and before starting the second writing processing, the mark deviation amount calculation unit 67 calculates a positional deviation amount (mark deviation amount) of a representative position in each global mesh region 11 in which any one of the alignment marks 14 is included. The positional deviation amount of each global mesh region 11 in which any one of the alignment marks 14 is included is calculated as a mark deviation amount (dxmark-n, dymark-n). n indicates the index of each global mesh region 11. The mark deviation amount (dxmark-n, dymark-n) of each global mesh region 11, where each one of the alignment marks 14 is included, after completion of the first writing processing depends on a dose (irradiation coefficient) defined in the dose map, and, as described above, can be similarly calculated using a finite element method, for example. Data of the calculated mark deviation amount (dxmark-n, dymark-n) is stored in the storage device 142.

Whichever of the development/etching/resist-application step (S186) and the mark deviation amount calculation step (S188) may be first performed. Alternatively, they may be performed simultaneously.

In the second mark measurement step (S190), in the state where the target object 101 was carried out once from the stage 105, and, then, newly placed on the stage 105 for the second writing processing, the mark position (the second mark position) of the alignment mark 14 is measured before starting the second writing processing. The method of measuring the mark position may be the same as that of the first mark measurement step (S180).

Data of chip patterns written in the first writing processing and the second writing processing have been generated on the premise that there is no irreversible deformation of the target object 101 due to beam irradiation. Therefore, if a chip pattern is written in the second writing processing based on each mark position measured in the second mark measurement step (S190), the relative position between the pattern written in the first writing processing and the pattern written in the second writing processing deviates by a positional deviation amount due to an irreversible deformation of the target object 101. Then, according to the fourth embodiment, the mark position to be a basis in the second writing processing is corrected by a positional deviation amount due to an irreversible deformation of the target object 101, based on a measurement result. It is specifically described below.

In the mark position correction step (S192), before starting the second writing processing, the mark position correction unit 69 calculates a mark position (the third mark position) by correcting the measured mark position (the second mark position) by a mark positional deviation amount (dxmark-n, dymark-n). Since the target object 101 has been carried out once from the stage 105, another positional deviation different from the one due to an irreversible deformation of the target object 101 in the first writing processing has further been generated between the position on the stage 105 of the target object 101 at the time of the first mark measurement step (S180) and that at the time of the second mark measurement step (S190). Therefore, in the mark position correction step (S192), the mark position measured in the second mark measurement step (S190) can be corrected by a positional deviation amount of the alignment mark 14 due to an irreversible deformation of the target object 101 in the first writing processing.

In the second GMC correction step (S194), the GMC correction unit 68 performs grid matching correction of the pattern data, on the basis of a corrected position (the third mark position) of each measured alignment mark 14. For example, regarding the lower left mark position on the target object 101 as the original point, the x axis connecting the original point and the lower right mark position and the y axis connecting the original point and the upper left mark position are set. The position of the chip pattern (the second chip pattern) written on the target object 101 in the second writing processing is defined based on a corrected mark position (the third mark position). Therefore, the GMC correction unit 68 corrects pattern data such that the coordinate system of the pattern data defined in writing data is in accordance with the x and y axes. Thereby, based on the original points obtained from a plurality of corrected alignment marks 14, processes of parallel translation, rotation, and reduction/enlargement may be performed for each pattern data. The method of data conversion is not described here since it may be the same as the conventional one.

In the second writing step (S196), the shot data generation unit 70 calculates, for each pixel 36, an incident dose D(x) (amount of dose) with which the pixel 36 concerned is irradiated in the second writing processing. In other words, the incident dose D(x) (amount of dose) is calculated by multiplying the dose defined in the dose map by the base dose D_{base}. If the incident dose D(x) (amount of dose) is defined in the dose map, it may be used as it is.

Next, the shot data generation unit 70 calculates an irradiation time for each pixel 36 for the second writing processing. The irradiation time for each pixel 36 can be obtained by diving an incident dose D(x) of a pixel concerned by a current density J.

The data processing unit 72 rearranges obtained irradiation time data for each pixel 36 in the order of shot for the second writing processing, and stores it in the storage device 142. The transmission processing unit 74 transmits, in the order of shot, the irradiation time data to the deflection control circuit 130.

Under the control of the writing control unit 76, the writing mechanism 150 writes a pattern on the target object 101 with the multiple beams 20 (electron beam), based on the beam irradiation position corrected by the correction amount (dx2ndn, dy2ndn). In other words, the writing mechanism 150 performs the second correction in the second writing processing, based on a difference between the writing-time positional deviation amount in the second writing processing and the final positional deviation amount. The writing mechanism 150 performs writing while moving the XY stage 105. Specifically, under the control of the deflection control circuit 130 (an example of a correction unit), for each tracking cycle of the multiple beams 20, the deflector 208 deflects a beam array (irradiation region) to a position corrected by a correction amount (dx2ndn, dy2ndn) of the global mesh region 11 where a representative position (e.g., center position or center beam position) of the beam array is included. The deflection position of the beam array (irradiation region 34) is set based on the representative position (e.g., a center position or center beam position) of the beam array described above.

In a modified example of the fourth embodiment, similarly to the modified example of the second embodiment, the formation position of a pattern may be corrected in pattern data.

In the modified example of the fourth embodiment, in the first writing step (S194), the shot data generation unit 70, first, corrects a pattern formation position in the writing data, based on the first correction amount map whose element value is a correction amount (dx1stn, dy1stn) for the first writing processing for each global mesh region 11 (xn, yn). Specifically, it operates as follows: The shot data generation unit 70 corrects, for each global mesh region 11, the position of a pattern included in the global mesh region 11 concerned by a correction amount defined for the global mesh region 11 concerned.

Then, the shot data generation unit 70 newly generates a dose map for the first writing processing by using a corrected pattern layout. The contents of the method of generating a dose map is the same as those described above. The shot data generation unit 70 calculates an irradiation time for each pixel 36. The irradiation time for each pixel 36 can be calculated by dividing an incident dose D(x) of a pixel concerned by a current density J.

The data processing unit 72 rearranges obtained irradiation time data for each pixel 36 in the order of shot, and stores it in the storage device 142. The transmission processing unit 74 transmits the irradiation time data to the deflection control circuit 130 in the order of shot.

Under the control of the writing control unit 76, the writing mechanism 150 writes a pattern on the target object 101 with the multiple beams 20 (electron beam) as the first writing processing, based on the beam irradiation position corrected by the correction amount. In the modified example of the fourth embodiment, in both the real time mode and the preprocessing mode, the position of a pattern has already been corrected by the correction amount (dx1stn, dy1stn) in pattern data. Therefore, in performing writing, under the control of the deflection control circuit 130, the deflector 208 deflects, in each tracking cycle, a representative position (e.g., center position or center beam position) of the beam array to its design position, and during the tracking cycle, at that position, while each beam writes (exposes), for example, four pixels 36, the beam array (irradiation region 34) is made to follow the movement of the XY stage 105 by collectively deflecting all of the multiple beams 20 by the deflector 208 in order that the relative position between the beam array (irradiation region 34) and the target object 101 may not be displaced by the movement of the XY stage 105.

Similarly, in the second writing step (S196), the shot data generation unit 70, first, corrects a pattern formation position in the writing data, based on the second correction amount map whose element value is a correction amount (dx2ndn, dy2ndn) for the second writing processing of each global mesh region (xn, yn). Specifically, it operates as follows: The shot data generation unit 70 corrects, for each global mesh region 11, the position of a pattern included in the global mesh region 11 concerned by a correction amount defined for the global mesh region 11 concerned.

Then, the shot data generation unit 70 newly generates a dose map for the first writing processing by using a corrected pattern layout. The contents of the method of generating a dose map is the same as those described above. The shot data generation unit 70 calculates an irradiation time for each pixel 36. The irradiation time for each pixel 36 can be calculated by dividing an incident dose D(x) of the pixel concerned by a current density J.

The data processing unit 72 rearranges obtained irradiation time data for each pixel 36 in the order of shot, and stores it in the storage device 142. The transmission processing unit 74 transmits the irradiation time data to the deflection control circuit 130 in the order of shot.

Under the control of the writing control unit 76, the writing mechanism 150 writes a pattern on the target object 101 with the multiple beams 20 (electron beam) as the second writing processing, based on the beam irradiation position corrected by the correction amount. In the modified example of the fourth embodiment, in both the real time mode and the preprocessing mode, the position of a pattern has already been corrected by the correction amount (dx2ndn, dy2ndn) in pattern data. Therefore, in performing writing, under the control of the deflection control circuit 130, the deflector 208 deflects, in each tracking cycle, a representative position (e.g., center position or center beam position) of the beam array to its design position, and during the tracking cycle, at that position, while each beam writes (exposes), for example, four pixels 36, the beam array (irradiation region 34) is made to follow the movement of the XY stage 105 by collectively deflecting all of the multiple beams 20 by the deflector 208 in order that the relative position between the beam array (irradiation region 34) and the target object 101 may not be displaced by the movement of the XY stage 105.

As described above, according to the fourth embodiment, it is possible to correct a positional deviation of the beam irradiation position and pattern formation position in superimposed writing deviated because of an irreversible deformation of the target object 101 due to irradiation of the multiple beams 20 (electron beam).

### Fifth Embodiment

A fifth embodiment describes the case where, relating to the superimposed writing explained in the fourth embodiment, when writing is performed without correction in the first writing processing, the second writing processing is performed such that the relative position with respect to the position written in the first writing processing is maintained. The configuration of the writing apparatus 100 of the fifth embodiment is the same as that of FIG. 24 except that the final positional deviation amount calculation unit 52, the correction amount calculation unit 56, and the correction amount map generation unit 58 are omitted.

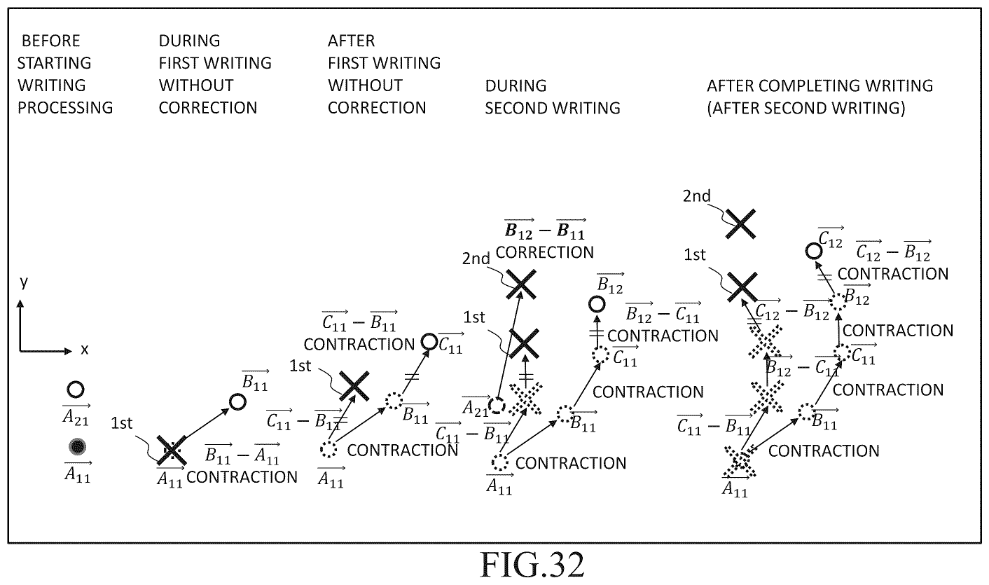

FIG. 32 is an illustration showing an example of a positional deviation state of a substrate surface according to the fifth embodiment. FIG. 32 shows a state before starting the first writing processing, a state during writing at a desired position in the first writing processing, a state after completing the first writing processing, a state during writing at a desired position in the second writing processing, and a state after completing the second writing process.

In FIG. 32, the vector A₁₁ indicates a design beam irradiation position in the first writing processing, and the vector A₂₁ indicates a design beam irradiation position in the second writing processing. While the first writing processing proceeds for the target LTEM substrate, if the position of the vector A₁₁ before starting writing processing is written as it is without correcting, at the time of writing the position of the vector A₂₁ in the second writing processing, the position of the vector A₁₁ before starting writing processing has physically moved, by a vector of (vector B₁₂−vector B₁₁), from the position of the vector A₁₁ before starting writing processing to the moved position (vector A₁₁+(vector B₁₂−vector B₁₁)) because a deformation due to contraction of the substrate occurred as shown in FIG. 32. Similarly, the position of the vector A₂₁ before starting writing processing has physically moved, by a vector of (vector B₁₂−vector B₁₁), from the position of the vector A₂₁ before starting writing processing to the moved position (vector A₂₁+(vector B₁₂−vector B₁₁)) because a deformation due to contraction of the substrate occurred as shown in FIG. 32.

In the fifth embodiment, since the second writing processing is performed using a different layout pattern from that of the first writing processing, superimposed writing is performed in the second writing processing, with maintaining the state of the relative positional relationship with respect to a beam irradiation position in the first writing processing. Therefore, at the time of writing in the second writing processing, the corrected position (vector A₂₁+(vector B₁₂−vector B₁₁)) corrected by a vector (the vector B₁₂−vector B₁₁) from the position of the vector A₂₁ before starting the processing is written as a beam irradiation position (or pattern formation position). Thereby, at the time of completion of the writing processing for the whole substrate after the second writing processing, the beam irradiation position (or pattern formation position) written in the first writing processing and the beam irradiation position (or pattern formation position) written in the second writing processing can have the same relative positional relationship although being different from the positions of the vector A₁₁ and A₂₁ before starting writing processing.

The contents of the flowchart showing some portions of an example of main steps of a writing method according to the fifth embodiment are the same as FIG. 27 except that the final positional deviation amount (vector C₁₂) calculation step (S103), the correction amount calculation step (S123), the determination step (S124), and the first correction amount map generation step (S127) are omitted. The contents of the flowchart showing other portions of the example of the main steps of the writing method according to the fifth embodiment are the same as FIG. 28. In the fifth embodiment, since no correcting is carried out in first writing processing, calculation for obtaining a correction amount is not performed in first writing processing.

The contents of the dose map generation step (S101), the writing schedule generation step (S107), and the writing-time positional deviation amount (vector B₁₁) calculation step according to the fifth embodiment are the same as those of the dose map generation step (S101), the writing schedule generation step (S107), and the writing-time positional deviation amount (vector B₁₁) calculation step (S121) of FIG. 27 explained in the fourth embodiment. In other words, in the writing-time positional deviation amount (vector B₁₁) calculation step (S121), when writing a pattern with electron beam irradiation on the target object 101 which deforms irreversibly depending on an electron beam dose distribution, the writing-time positional deviation amount calculation unit 54 calculates, in the first writing processing for writing the first chip pattern, a writing-time positional deviation amount (the first positional deviation amount) of the first chip pattern deviated from its design position because of an irreversible deformation of the target object 101 generated by electron beam irradiation onto the target object 101 having been performed before the irradiation of the current electron beam concerned.

The contents of the writing-time positional deviation amount (vector B₁₂) calculation step (S131) according to the fifth embodiment are the same as those of the writing-time positional deviation amount (vector B₁₂) calculation step (S131) of FIG. 27 explained in the fourth embodiment. In other words, in the writing-time positional deviation amount (vector B₁₂) calculation step (S131), the positional deviation amount calculation unit 62 calculates, in the second writing processing for writing the second chip pattern to be superimposed (overlapped) on the first chip pattern, a writing-time positional deviation amount (the second positional deviation amount) of the second chip pattern deviated from its design position because of an irreversible deformation of the target object 101 generated by electron beam irradiation onto the target object 101 having been performed before the irradiation of the current electron beam concerned.

In the correction amount calculation step (S133), based on a positional deviation amount (vector B₁₁), the correction amount calculation unit 64 calculates a correction amount (vector B₁₂−vector B₁₁) (another example of the first correction amount) for correcting a pattern formation position or a beam irradiation position of a pattern in the case of applying an electron beam concerned in the second writing processing corresponding to the electron beam concerned in the first writing processing. Based on a difference between the writing-time positional deviation amount (vector B₁₂) in the second writing processing and the writing-time positional deviation amount (vector B₁₁) in the first writing processing, a correction amount (vector B₁₂−vector B₁₁) (another example of the first correction amount) for correcting a pattern position or an electron beam irradiation position when forming a pattern with an electron beam on the target object 101 is calculated in the second writing processing. In other words, the correction amount (dx2ndn, dy2ndn) of each position in the n-th beam-irradiated (written) global mesh region 11 can be calculated by a subtraction of “the writing-time positional deviation amount (dx2ndwrite-n, dy2ndwrite-n)”−“the writing-time positional deviation amount (dx1stwrite-n, dy1stwrite-n)”.

The contents of the determination step (S134) and the second correction amount map generation step (S137) according to the fifth embodiment are the same as those of the determination step (S134) and the second correction amount map generation step (S137) of FIG. 27 explained in the fourth embodiment.

The contents of the first mark measurement step (S180) and the first GMC correction step (S182) according to the fifth embodiment are the same as those of the first mark measurement step (S180) and the first GMC correction step (S182) of FIG. 28.

The writing mechanism 150 of the fifth embodiment corrects, based on a difference between the writing-time positional deviation amount in the second writing processing and the writing-time positional deviation amount in the first writing processing, a pattern position or an electron beam irradiation position when forming a pattern with an electron beam on the target object 101 in the second writing processing. Further, the writing mechanism 150 performs the second writing processing of writing the second chip pattern on the target object 101, based on the first writing processing of writing the first chip pattern on the target object 101 and the correction amount described above. It is specifically described below.

In the first writing step (S184), the shot data generation unit 70 calculates an irradiation time for each pixel 36 by using the dose map for the first writing processing. The irradiation time for each pixel 36 can be calculated by dividing an incident dose D(x) of a pixel concerned by a current density J.

The data processing unit 72 rearranges obtained irradiation time data for each pixel 36 in the order of shot, and stores it in the storage device 142. The transmission processing unit 74 transmits the irradiation time data to the deflection control circuit 130 in the order of shot.

Under the control of the writing control unit 76, the writing mechanism 150 writes a pattern on the target object 101 with the multiple beams 20 (electron beam) as the first writing processing. In the fifth embodiment, in both the real time mode and the preprocessing mode, in performing writing, under the control of the deflection control circuit 130, the deflector 208 deflects, in each tracking cycle, a representative position (e.g., center position or center beam position) of the beam array to its design position, and during the tracking cycle, at that position, while each beam writes (exposes), for example, four pixels 36, the beam array (irradiation region 34) is made to follow the movement of the XY stage 105 by collectively deflecting all of the multiple beams 20 by the deflector 208 in order that the relative position between the beam array (irradiation region 34) and the target object 101 may not be displaced by the movement of the XY stage 105.

The contents of each step from the development/etching/resist-application step (S186) to the second GMC correction step (S194) are the same as those of each step from the development/etching/resist-application step (S186) to the second GMC correction step (S194) of FIG. 28 explained in the fourth embodiment.

In the second writing step (S196), the shot data generation unit 70 calculates, for each pixel 36, an incident dose D(x) (amount of dose) with which the pixel 36 concerned is irradiated in the second writing processing. In other words, the incident dose D(x) (amount of dose) is calculated by multiplying the dose defined in the dose map by the base dose D_{base}. If the incident dose D(x) (amount of dose) is defined in the dose map, it may be used as it is.

Next, the shot data generation unit 70 calculates an irradiation time for each pixel 36 for the second writing processing. The irradiation time for each pixel 36 can be obtained by diving an incident dose D(x) of a pixel concerned by a current density J.

The data processing unit 72 rearranges obtained irradiation time data for each pixel 36 in the order of shot for the second writing processing, and stores it in the storage device 142. The transmission processing unit 74 transmits, in the order of shot, the irradiation time data to the deflection control circuit 130.

Under the control of the writing control unit 76, the writing mechanism 150 writes a pattern on the target object 101 with the multiple beams 20 (electron beam), based on the beam irradiation position corrected by the correction amount (dx2ndn, dy2ndn). The writing mechanism 150 performs writing while moving the XY stage 105. Specifically, under the control of the deflection control circuit 130 (an example of a correction unit), for each tracking cycle of the multiple beams 20, the deflector 208 deflects a beam array (irradiation region) to a position corrected by a correction amount (dx2ndn, dy2ndn) of the global mesh region 11 where a representative position (e.g., center position or center beam position) of the beam array is included. The deflection position of the beam array (irradiation region 34) is set based on the representative position (e.g., a center position or center beam position) of the beam array described above.

In a modified example of the fifth embodiment, similarly to the modified example of the fourth embodiment, the formation position of a pattern may be corrected in pattern data.

In the modified example of the fifth embodiment, the contents of the first writing step (S194) are the same as those of the first writing step (S194) of the fifth embodiment.

In the second writing step (S196) according to the modified example of the fifth embodiment, the shot data generation unit 70, first, corrects a pattern formation position in the writing data, based on the correction amount map whose element value is a correction amount (dx2ndn, dy2ndn) for the second writing processing for each global mesh region 11 (xn, yn). Specifically, it operates as follows: The shot data generation unit 70 corrects, for each global mesh region 11, the position of a pattern included in the global mesh region 11 concerned by a correction amount defined for the global mesh region 11 concerned.

Then, the shot data generation unit 70 newly generates a dose map for the first writing processing by using a corrected pattern layout. The contents of the method of generating a dose map is the same as those described above. The shot data generation unit 70 calculates an irradiation time for each pixel 36. The irradiation time for each pixel 36 can be calculated by dividing an incident dose D(x) of a pixel concerned by a current density J.

The data processing unit 72 rearranges obtained irradiation time data for each pixel 36 in the order of shot, and stores it in the storage device 142. The transmission processing unit 74 transmits the irradiation time data to the deflection control circuit 130 in the order of shot.

Under the control of the writing control unit 76, the writing mechanism 150 writes a pattern on the target object 101 with the multiple beams 20 (electron beam) as the second writing processing, based on the beam irradiation position corrected by the correction amount. In the modified example of the fifth embodiment, in both the real time mode and the preprocessing mode, the position of a pattern has already been corrected by the correction amount (dx2ndn, dy2ndn) in pattern data. Therefore, in performing writing, under the control of the deflection control circuit 130, the deflector 208 deflects, in each tracking cycle, a representative position (e.g., center position or center beam position) of the beam array to its design position, and during the tracking cycle, at that position, while each beam writes (exposes), for example, four pixels 36, the beam array (irradiation region 34) is made to follow the movement of the XY stage 105 by collectively deflecting all of the multiple beams 20 by the deflector 208 in order that the relative position between the beam array (irradiation region 34) and the target object 101 may not be displaced by the movement of the XY stage 105.

As described above, according to the fifth embodiment, even when correcting a positional deviation of a beam irradiation position or a pattern formation position is not performed in the first writing processing in the superimposed writing, a positional deviation of a beam irradiation position or a pattern formation position due to an irreversible deformation of the target object 101 resulting from irradiation of the multiple beams 20 (electron beam) can be corrected in the second writing processing.

Embodiments have been explained referring to specific examples described above. However, the present invention is not limited to these specific examples. Functions of processing described in each embodiment may be executed by a computer. A program for causing a computer to implement such functions of processing may be stored in a non-transitory tangible computer-readable storage medium such as a magnetic disc device.

While the apparatus configuration, control method, and the like not directly necessary for explaining the present invention are not described, some or all of them can be appropriately selected and used on a case-by-case basis when needed. For example, although description of the configuration of the control unit for controlling the writing apparatus 100 is omitted, it should be understood that some or all of the configuration of the control unit can be selected and used appropriately when necessary.

Further, any electron beam writing method, electron beam writing apparatus, and program that include elements of the present invention and that can be appropriately modified by those skilled in the art are included within the scope of the present invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An electron beam writing method comprising:
calculating, in a case of writing a pattern with an electron beam on a target object which irreversibly deforms depending on a dose distribution of the electron beam, a first positional deviation amount of the pattern deviated from its design position because of an irreversible deformation of the target object after completion of writing processing;
calculating, based on the first positional deviation amount, a correction amount for correcting one of a position of the pattern and an irradiation position of an electron beam in forming the pattern by irradiation of the electron beam on the target object; and
performing, based on the correction amount, writing processing to write the pattern on the target object with an electron beam.

2. The method according to claim 1, further comprising:
calculating, in the writing processing, a second positional deviation amount of the pattern deviated from its design position because of an irreversible deformation of the target object generated by irradiation of an electron beam on the target object having been performed before irradiation of an electron beam currently performed,
wherein the correcting is performed based on a difference between the second positional deviation amount and the first positional deviation amount.

3. The method according to claim 1, wherein
the writing processing includes first writing processing to write a first chip pattern, and second writing processing, performed after the first writing processing, to write a second chip pattern to be superimposed on the first chip pattern, and
the first positional deviation amount is a positional deviation amount of the pattern deviated from its design position due to an irreversible deformation of the target object after completion of the second writing processing.

4. The method according to claim 3, further comprising:
calculating, in the first writing processing, a second positional deviation amount of the pattern deviated from its design position because of an irreversible deformation of the target object generated by irradiation of an electron beam on the target object having been performed before irradiation of an electron beam currently performed in the first writing processing; and
calculating, in the second writing processing, a third positional deviation amount of the pattern deviated from its design position because of an irreversible deformation of the target object generated by irradiation of an electron beam on the target object having been performed before irradiation of an electron beam currently performed in the second writing processing,
wherein the calculating the correction amount includes
calculating a first correction amount in the first writing processing, based on a difference between the second positional deviation amount and the first positional deviation amount, and
calculating a second correction amount in the second writing processing, based on a difference between the third positional deviation amount and the first positional deviation amount.

5. The method according to claim 3, wherein
on the target object, a mark for alignment is formed in advance, and the target object is placed on a movable stage, further comprising:
measuring a first mark position of the mark before the first writing processing;
calculating a positional deviation amount of the mark deviated from the first mark position due to an irreversible deformation of the target object after completing the first writing processing;
measuring, in a state where the target object was carried out once from the stage, and, then, newly placed on the stage for the second writing processing, a second mark position of the mark before starting the second writing processing; and
calculating a third mark position by correcting the second mark position by the positional deviation amount of the mark before starting the second writing processing,
wherein a position of the first chip pattern written on the target object in the first writing processing is defined based on the first mark position, and
a position of the second chip pattern written on the target object in the second writing processing is defined based on the third mark position.

6. An electron beam writing apparatus comprising:
a stage configured to mount thereon a target object which deforms irreversibly depending on a dose distribution of an electron beam;
a first positional deviation amount calculation circuit configured to calculate, in a case of writing a pattern with the electron beam on the target object, a first positional deviation amount of the pattern deviated from its design position because of an irreversible deformation of the target object after completion of the writing;
a correction amount calculation unit configured calculate, based on the first positional deviation amount, a correction amount for correcting one of a position of the pattern and an irradiation position of an electron beam in forming the pattern by irradiation of the electron beam on the target object; and
a writing mechanism configured to write the pattern on the target object with an electron beam, based on the correction amount.

7. A non-transitory computer-readable tangible storage medium storing a program for causing a computer to execute processing comprising:
calculating, in a case of writing a pattern with an electron beam on a target object which irreversibly deforms depending on a dose distribution of the electron beam, a first positional deviation amount of the pattern deviated from its design position because of an irreversible deformation of the target object after completion of writing processing;
storing the first positional deviation amount in a storage device; and
reading the first positional deviation amount from the storage device, calculating, based on the first positional deviation amount, a correction amount for correcting one of a position of the pattern and an irradiation position of an electron beam in forming the pattern by irradiation of the electron beam on the target object, and outputting the correction amount.

8. An electron beam writing method comprising:
calculating, in first writing processing for writing a first chip pattern with an electron beam on a target object which irreversibly depending on a dose distribution of the electron beam, a first positional deviation amount of the first chip pattern deviated from its design position because of an irreversible deformation of the target object generated by irradiation of an electron beam on the target object having been performed before irradiation of an electron beam currently performed in the first writing processing;
calculating, in second writing processing for writing a second chip pattern to be superimposed on the first chip pattern, a second positional deviation amount of the second chip pattern deviated from its design position because of an irreversible deformation of the target object generated by irradiation of an electron beam on the target object having been performed before irradiation of an electron beam currently performed in the second writing processing;
calculating, based on a difference between the second positional deviation amount and the first positional deviation amount, a correction amount for correcting one of a position of the pattern and an irradiation position of the electron beam in a case of forming the pattern on the target object by applying the electron beam to the target object in the second writing processing; and
performing the first writing processing of writing the first chip pattern on the target object with an electron beam, and the second writing processing of writing the second chip pattern on the target object with an electron beam, based on the correction amount.

9. The method according to claim 8, wherein, at a time of the applying the electron beam to the target object in the second writing processing, the electron beam is applied to a position overlapping with an irradiation position of the electron beam in the first writing processing.

10. The method according to claim 8, wherein the second chip pattern is written in the second writing processing to be superimposed on the first chip pattern with maintaining a state of a relative positional relationship between an irradiation position of an electron beam in the first writing processing and an irradiation position of an electron beam in the second writing processing.

11. An electron beam writing apparatus comprising:
a stage configured to mount thereon a target object which deforms irreversibly depending on a dose distribution of an electron beam;
a positional deviation amount calculation circuit configured to calculate, in first writing processing for writing a first chip pattern with the electron beam on the target object, a first positional deviation amount of the first chip pattern deviated from its design position because of an irreversible deformation of the target object generated by irradiation of an electron beam on the target object having been performed before irradiation of an electron beam currently performed in the first writing processing, and to calculate, in second writing processing for writing a second chip pattern to be superimposed on the first chip pattern, a second positional deviation amount of the second chip pattern deviated from its design position because of an irreversible deformation of the target object generated by irradiation of an electron beam on the target object having been performed before irradiation of an electron beam currently performed in the second writing processing;
a correction amount calculation circuit configured to calculate, based on a difference between the second positional deviation amount and the first positional deviation amount, a correction amount for correcting one of a position of the pattern and an irradiation position of an electron beam in a case of forming the pattern on the target object by applying the electron beam to the target object in the second writing processing; and
a writing mechanism configured to perform the first writing processing of writing the first chip pattern on the target object with an electron beam, and the second writing processing of writing the second chip pattern on the target object with an electron beam, based on the correction amount.

12. A non-transitory computer-readable tangible storage medium storing a program for causing a computer to execute processing comprising:
calculating, in first writing processing for writing a first chip pattern with an electron beam on a target object which deforms irreversibly depending on a dose distribution of the electron beam, a first positional deviation amount of the first chip pattern deviated from its design position because of an irreversible deformation of the target object generated by irradiation of an electron beam on the target object having been performed before irradiation of an electron beam currently performed in the first writing processing;
calculating, in second writing processing for writing a second chip pattern to be superimposed on the first chip pattern, a second positional deviation amount of the second chip pattern deviated from its design position because of an irreversible deformation of the target object generated by irradiation of an electron beam on the target object having been performed before irradiation of an electron beam currently performed in the second writing processing;
storing the first positional deviation amount and the second positional deviation amount in a storage device; and
reading the first positional deviation amount and the second positional deviation amount from the storage device, calculating, based on a difference between the second positional deviation amount and the first positional deviation amount, a correction amount for correcting one of a position of the pattern and an irradiation position of an electron beam in a case of forming the pattern on the target object by applying the electron beam to the target object in the second writing processing, and outputting the correction amount.
